(19) United States
(12) Patent Application Publication
(10) Pub. No.: US 2025/0201310 A1
(43) Pub. Date: Jun. 19, 2025

(54) THREE-DIMENSIONAL MEMORY DEVICE

(71) Applicant: SAMSUNG ELECTRONICS CO., LTD., Suwon-si (KR)

(72) Inventors: Namhyuk Kim, Suwon-si (KR); Kyunghwa Yun, Suwon-si (KR); Chanho Kim, Suwon-si (KR)

(21) Appl. No.: 18/889,171

(22) Filed: Sep. 18, 2024

(30) Foreign Application Priority Data
Dec. 15, 2023 (KR) 10-2023-0183460

(51) Int. Cl. G11C 16/08; G11C 5/06; H10B 41/40; H10B 43/40

(52) U.S. Cl. CPC G11C 16/08; G11C 5/063; H10B 41/40; H10B 43/40

(57) ABSTRACT

A memory device includes a first semiconductor layer including a peripheral circuit therein and a second semiconductor layer stacked on the first semiconductor layer in a vertical direction and including a memory cell array electrically connected to the peripheral circuit. The first semiconductor layer includes a page buffer area in which a page buffer circuit is disposed, the second semiconductor layer includes a cell area in which a plurality of bit lines is arranged at regular intervals along a first direction, and a length in the first direction of the page buffer area is different from a length in the first direction of the cell area.

### CROSS-REFERENCE TO RELATED APPLICATION(S)

This application claims priority to Korean Patent Application No. 10-2023-0183460, filed in the Korean Intellectual Property Office on Dec. 15, 2023, the disclosure of which is incorporated by reference herein in its entirety.

### BACKGROUND

Memory devices are used to store data and classified into volatile memory devices and nonvolatile memory devices. As an example of the nonvolatile memory device, a flash memory device is used in a mobile phone, a digital camera, a mobile computing device, a fixed computing device, and other devices,

In recent, as information communication devices are being developed to have a multitude of functions, memories for such devices can benefit from a large capacity and a high degree of integration. Accordingly, a three-dimensional (3D) nonvolatile memory device that includes a plurality of word lines stacked on a substrate along a vertical direction is being suggested. As the number of layers of word lines stacked on the substrate increases rapidly, a size of a memory cell array is reduced. However, when the size of a peripheral circuit is not reduced even though the size of the memory cell array is reduced, the overall size of a chip does not decrease. Accordingly, efficiently arranging the circuit elements constituting the peripheral circuit is desirable to reduce the chip size.

### SUMMARY

In general, in some aspects, the present disclosure is directed toward a memory device capable of reducing a size of a chip, in which a length in a first direction of a page buffer circuit is different from a length in the first direction of a memory cell array.

According to some implementations, the present disclosure is directed to a memory device that includes a first semiconductor layer comprising a peripheral circuit, and a second semiconductor layer stacked on the first semiconductor layer in a vertical direction and comprising a memory cell array electrically connected to the peripheral circuit, in which the first semiconductor layer comprises a page buffer area in which a page buffer circuit is disposed, the second semiconductor layer comprises a cell area in which a plurality of bit lines is arranged at regular intervals along a first direction, and a length in the first direction of the page buffer area is different from a length in the first direction of the cell area.

According to some implementations, the present disclosure is directed to a memory device that includes a first semiconductor layer comprising a peripheral circuit therein, and a second semiconductor layer stacked on the first semiconductor layer along a third direction that is a vertical direction and comprising a memory cell array therein, in which the first semiconductor layer comprises a plurality of page buffer units extending in a first direction and arranged in a second direction, the second semiconductor layer comprises a plurality of bit lines electrically connected to the page buffer units and arranged at regular intervals along the first direction, and a value obtained by multiplying a pitch in the first direction of the bit lines by a number of the page buffer units is greater than a length in the first direction of the page buffer units.

According to some implementations, the present disclosure is directed to a memory device that includes a first semiconductor layer comprising a peripheral circuit, and a second semiconductor layer stacked on the first semiconductor layer along a third direction that is a vertical direction and comprising a memory cell array therein, in which the first semiconductor layer comprising a plurality of page buffer units extending in a first direction and arranged in a second direction, the second semiconductor layer comprising a plurality of bit lines electrically connected to the page buffer units and arranged at regular intervals along the first direction, and a value obtained by multiplying a pitch in the first direction of the bit lines by a number of the page buffer units is smaller than a length in the first direction of the page buffer units.

### BRIEF DESCRIPTION OF THE DRAWINGS

Example implementations will be more clearly understood from the following detailed description, taken in conjunction with the accompanying drawings.

FIG. 1A is a block diagram illustrating an example of a memory device according to some implementations.

FIG. 1B is a view illustrating the memory device of FIG. 1A formed using two semiconductor layers according to some implementations.

FIG. 2 is a layout illustrating an example arrangement of components of the memory device of FIG. 1A according to some implementations.

FIG. 3 is a layout illustrating an example of an arrangement of components of the memory device of FIG. 1A according to some implementations.

FIG. 4 is a circuit diagram illustrating an example of a memory block among memory blocks included in a memory cell array of FIG. 1A according to some implementations.

FIG. 5 is a view illustrating an example of a row decoder of FIG. 1A according to some implementations.

FIG. 6A is a view illustrating an example of a page buffer unit included in a page buffer circuit of FIG. 1A and an example of a connection structure that electrically connects a bit line and a page buffer unit according to some implementations.

FIG. 6B is a view illustrating an example of a connection structure that electrically connects page buffer units included in a page buffer circuit of FIG. 1A and bit lines according to some implementations.

FIG. 7 is a view illustrating an example of a memory device according to some implementations.

FIGS. 8A and 8B are views illustrating an example arrangement of components of the memory device of FIG. 7 when viewed in a horizontal direction according to some implementations.

FIG. 9 is a cross-sectional view taken along a line A-A′ of FIGS. 8A and 8B according to some implementations.

FIG. 10 is a view illustrating an example arrangement relationship between bit lines and a sub-page buffer circuit of the memory device of FIG. 7 according to some implementations.

FIG. 11 is a view illustrating an example of a memory device according to some implementations.

FIG. 12 is a cross-sectional view illustrating the memory device of FIG. 11 according to some implementations.

FIG. 13 is a view illustrating an example of a memory device according to some implementations.

FIG. 14 is a cross-sectional view illustrating the memory device of FIG. 13 according to some implementations.

FIG. 15 is a view illustrating an example of a memory device according to some implementations.

FIG. 16 is a view illustrating an example arrangement relationship between bit lines and a sub-page buffer circuit of the memory device of FIG. 15 according to some implementations.

FIGS. 17 to 19 are views illustrating examples of arrangements of a page buffer area and a decoder area formed in a first semiconductor layer according to some implementations.

FIG. 20 is a cross-sectional view illustrating an example of a memory device according to some implementations.

### DETAILED DESCRIPTION

Hereinafter, example implementation will be explained in detail with reference to the accompanying drawings. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. Embodiments described herein are example embodiments, and thus, the present disclosure is not limited thereto, and may be realized in various other forms. Each example embodiment provided in the following description is not excluded from being associated with one or more features of another example or another example embodiment also provided herein or not provided herein but consistent with the present disclosure.

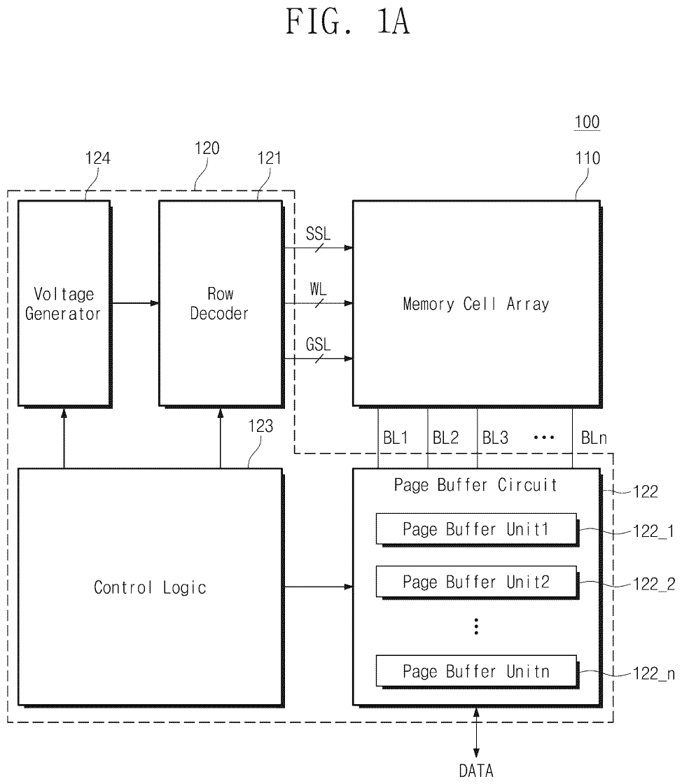

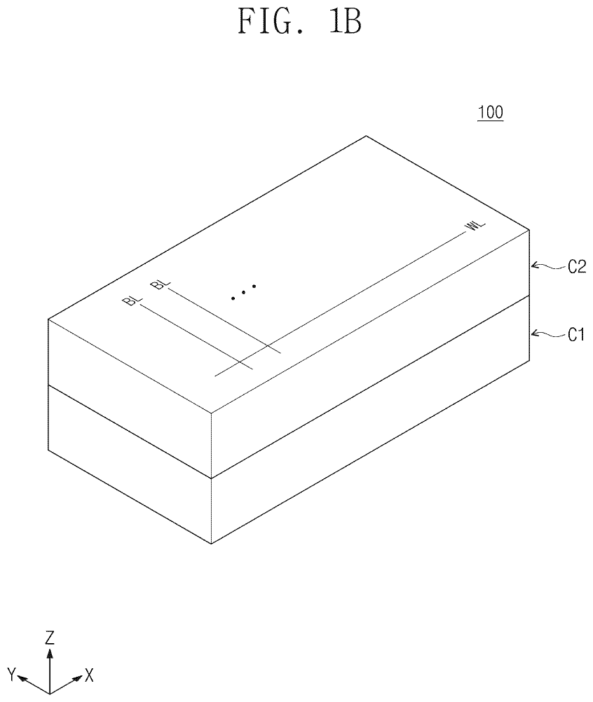

FIG. 1A is a block diagram illustrating an example of a memory device according to some implementations. FIG. 1B is a view illustrating the memory device of FIG. 1A formed using two semiconductor layers according to some implementations.

In FIGS. 1A and 1B, a memory device 100 may include a memory cell array 110 and a peripheral circuit 120. The memory cell array 110 may be formed in a second semiconductor layer C2, and the peripheral circuit 120 may be formed in a first semiconductor layer C1. In some implementations, a length in a first direction X of a page buffer circuit 122 of the peripheral circuit 120 may be different from a length in the first direction X of the memory cell array 110. Accordingly, an area to place peripheral circuit elements such as a row decoder 121 may be additionally secured even without an increase of a chip size. Consequently, the overall chip size of the memory device 100 may be reduced.

In FIGS. 1A and 1B, the memory device 100 may include the memory cell array 110 and the peripheral circuit 120. The peripheral circuit 120 may include the row decoder 121, the page buffer circuit 122, a control logic 123, and a voltage generator 124.

The memory cell array 110 may be connected to the page buffer circuit 122 via bit lines BL1 to BLn and may be connected to the row decoder 121 via word lines WL, string selection lines SSL, and ground selection lines GSL. The word lines WL, the string selection lines SSL, and the ground selection lines GSL may be referred to as row lines.

The memory cell array 110 may include a plurality of memory cells. As an example, the memory cells may be nonvolatile memory cells such as flash memory cells, however, the present disclosure should not be limited thereto or thereby. According to some implementations, the memory cells may be resistive memory cells, such as a resistive RAM (ReRAM), a phase change RAM (PRAM) or a magnetic RAM (MRAM). In addition, according to some implementations, the memory cells may be volatile memory cells, such as DRAM cells.

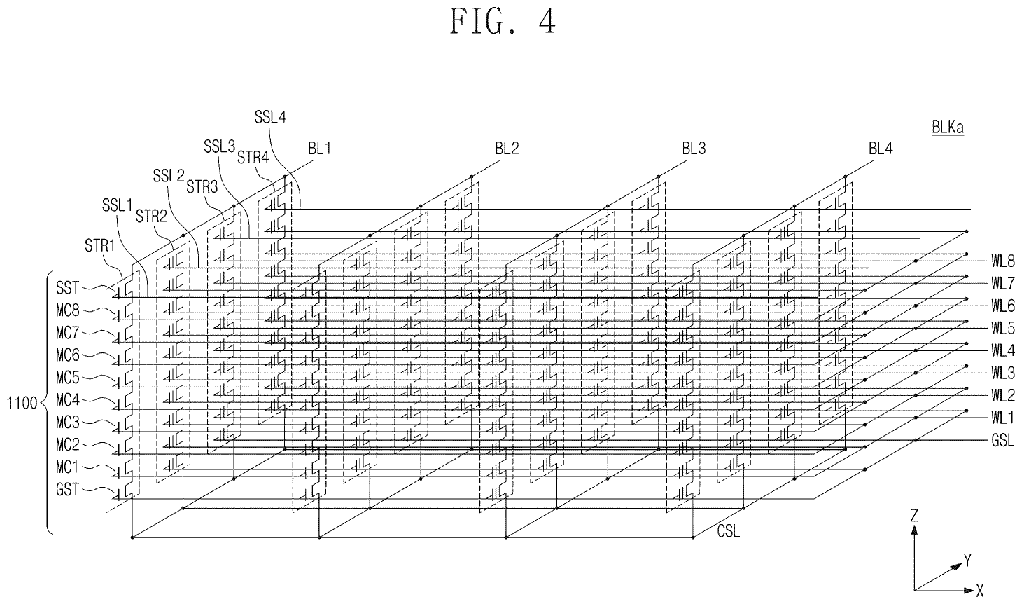

The memory cell array 110 may be implemented as a three-dimensional memory cell array. As an example, the three-dimensional memory cell array may include a plurality of NAND strings, and each NAND string may include memory cells that are respectively connected to word lines vertically stacked on a substrate. The memory cell array 110 will be described in detail later with reference to FIG. 4.

The row decoder 121 may select one of a plurality of memory blocks in response to a row address signal, may select one of the word lines WL of the selected memory block, and may select one of the string selection lines SSL.

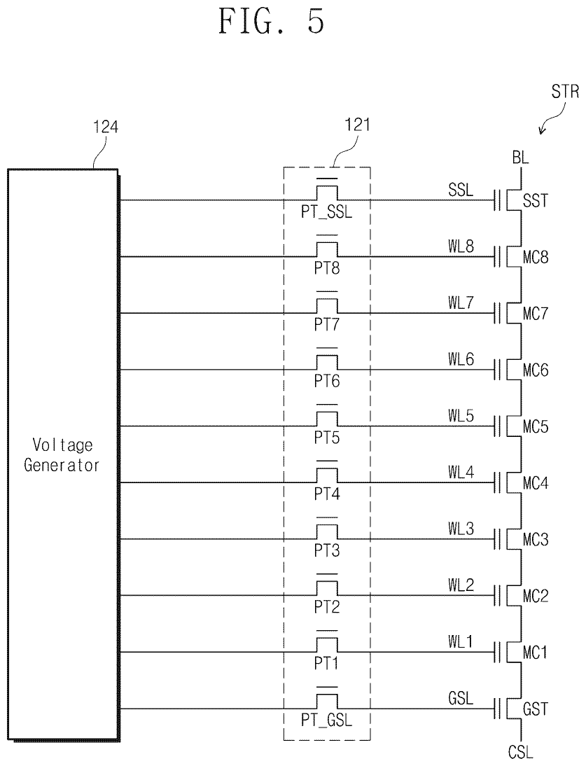

The row decoder 121 may include a plurality of pass transistors. As an example, the row decoder 121 may include the pass transistors corresponding to the word lines vertically stacked on the substrate. The row decoder 121 will be described in detail later with reference to FIG. 5.

The page buffer circuit 122 may select some bit lines among the bit lines BL1 to BLn in response to a column address signal. The page buffer circuit 122 may operate as a write driver or sense amplifier depending on an operation mode thereof.

The page buffer circuit 122 may include a plurality of page buffer units 122_1 to 122_n. The page buffer units 122_1 to 122_n may be electrically connected to the bit lines BL1 to BLn, respectively. As an example, a first page buffer unit 122_1 may be electrically connected to a first bit line BL1, and a second page buffer unit 122_2 may be electrically connected to a second bit line BL2.

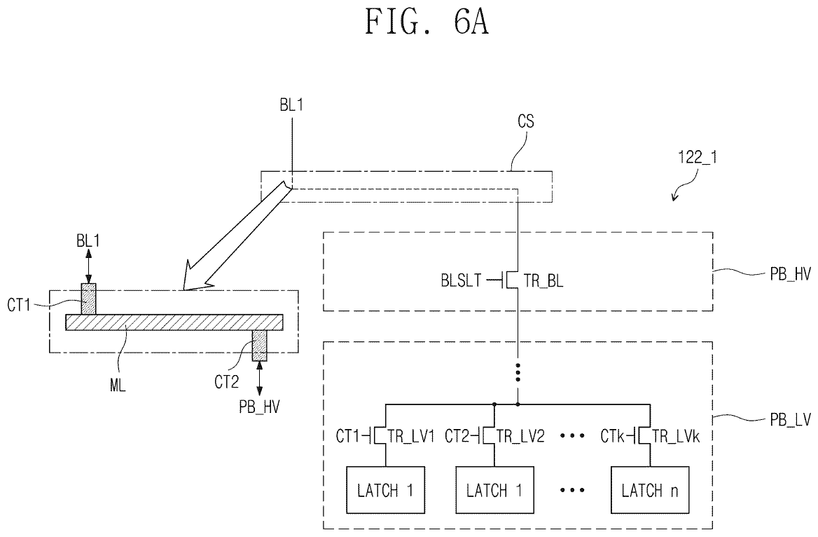

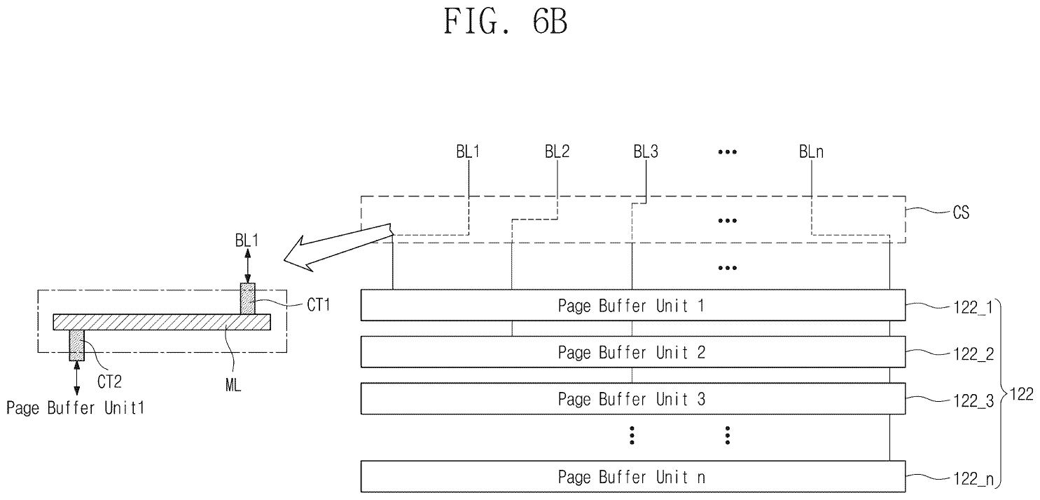

Each page buffer unit may include a high-voltage page buffer and a low-voltage page buffer. The high-voltage page buffer may include at least one high-voltage transistor, and the low-voltage page buffer may include at least one low-voltage transistor. The page buffer circuit 122 will be described in detail later with reference to FIGS. 6A and 6B.

The control logic 123 may generally control various operations within the memory device 100. As an example, the control logic 123 may program data DATA in the memory cell array 110 or may read the data DATA from the memory cell array 110 based on a command signal, an address signal, and a control signal.

The voltage generator 124 may generate various voltages to perform a program operation, a read operation, and an erase operation on the memory cell array 110. As an example, the voltage generator 124 may generate word line voltages, such as a program voltage, a read-out voltage, a pass voltage, an erase verification voltage, or a program verification voltage. In addition, the voltage generator 124 may further generate a string selection line voltage and a ground selection line voltage.

Additionally, the peripheral circuit 120 may further include a data input/output circuit or input/output interface, a column logic, a pre-decoder, a temperature sensor, a command decoder, an address decoder, etc.

In FIGS. 1A and 1B, the memory device 100 may include the first semiconductor layer C1 and the second semiconductor layer C2. The second semiconductor layer C2 may be stacked on the first semiconductor layer C1 in a vertical direction Z.

The memory cell array 110 may be formed in the second semiconductor layer C2. In addition, the bit lines BL and the word lines WL may be formed in the second semiconductor layer C2. The bit lines BL may extend in a second direction Y and may be arranged in the first direction X at regular intervals. The word lines WL may extend in the first direction X. As an example, the length in the first direction X of the memory cell array 110 may be equal to or similar to a length in the first direction X of an area in which the bit lines BL are arranged.

The peripheral circuit 120 may be formed in the first semiconductor layer C1. As an example, the row decoder 121 and the page buffer circuit 122 may be formed in the first semiconductor layer C1.

According to some implementations, the memory device 100 may have a chip-to-chip (C2C) structure. The C2C structure may refer to a structure which is formed by manufacturing a first chip including the peripheral circuit 120 in the first semiconductor layer C1, manufacturing a second chip including the memory cell array 110 in the second semiconductor layer C2 different from the first semiconductor layer C1, and connecting the first chip and the second chip by a bonding process.

According to some implementations, the memory device 100 may have a cell-over-periphery (COP) structure. The COP structure may include the first semiconductor layer C1 and the second semiconductor layer C2 disposed on the first semiconductor layer C1, the peripheral circuit 120 may be formed in the first semiconductor layer C1, and the memory cell array 110 may be formed in the second semiconductor layer C2.

According to the present disclosure, the length in the first direction X of the page buffer circuit 122 formed in the first semiconductor layer C1 may be different from the length in the first direction X of the memory cell array 110 formed in the second semiconductor layer C2. As an example, the length in the first direction X of the page buffer circuit 122 formed in the first semiconductor layer C1 may be shorter than the length in the first direction X of the memory cell array 110 formed in the second semiconductor layer C2 to further secure an area in which the row decoder 121 is disposed. As another example, the length in the first direction X of the page buffer circuit 122 formed in the first semiconductor layer C1 may be longer than the length in the first direction X of the memory cell array 110 formed in the second semiconductor layer C2 to further secure an area in which the peripheral circuit elements are disposed in addition to the row decoder 121.

As described above, as the length in the first direction X of the page buffer circuit 122 formed in the first semiconductor layer C1 is different the length in the first direction X of the memory cell array 110 formed in the second semiconductor layer C2, the memory device 100 according to the present disclosure may secure the area in which the peripheral circuit elements such as the row decoder 121 are disposed without additionally increasing the chip size.

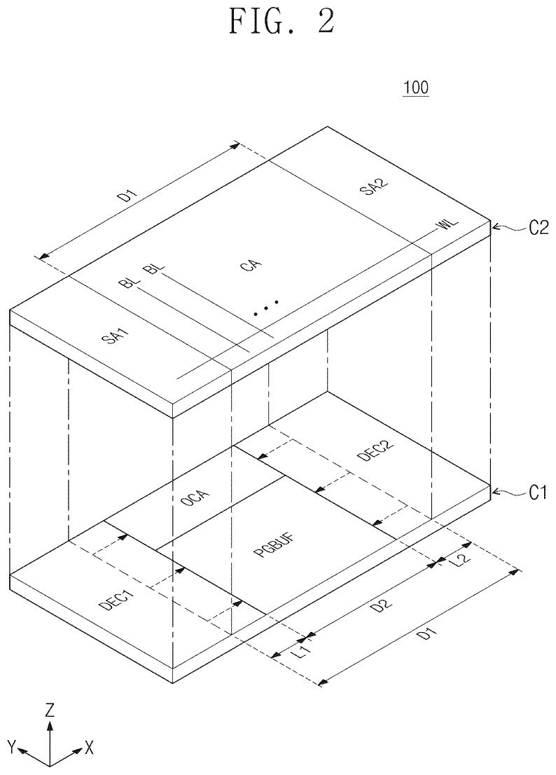

FIG. 2 is a layout illustrating an example arrangement of components of the memory device 100 of FIG. 1A according to some implementations. FIG. 2 shows a structure in which the length in the first direction X of the page buffer circuit 122 is shorter than the length in the first direction X of the memory cell array 110.

In FIG. 2, the memory device 100 may include the first and second semiconductor layers C1 and C2 stacked in the vertical direction. The first semiconductor layer C1 may include a page buffer area PGBUF, first and second decoder areas DEC1 and DEC2, and other circuit area OCA.

The page buffer circuit 122 of FIG. 1A may be disposed in the page buffer area PGBUF. The row decoder 121 of FIG. 1A may be disposed in the first and second decoder areas DEC1 and DEC2. The other peripheral circuit elements, such as the control logic 123 and the voltage generator 124 of FIG. 1A, may be disposed in the other circuit area OCA.

The second semiconductor layer C2 may include a cell area CA and first and second step areas SA1 and SA2.

The memory cell array 110 and the word lines WL of FIG. 1A may be disposed in the cell area CA and the first and second step areas SA1 and SA2. As an example, the strings including the memory cells and the bit lines BL may be disposed in the cell area CA. The bit lines BL may extend in the second direction Y and may be arranged at regular intervals in the first direction X.

One end and the other end of the word lines WL extending in the first direction X may be arranged in the first and second step areas SA1 and SA2 to have a step shape along the vertical direction, i.e., a third direction Z.

In some implementations, the page buffer circuit may be disposed to completely overlap the bit lines when viewed in a horizontal direction. As an example, when a length in the first direction X of the cell area CA included in the second semiconductor layer C2 is referred to as ‘D1’, a length in the first direction X of the page buffer area PGBUF included in the first semiconductor layer C1 may also be equal to ‘D1’.

However, as the number of stages of the row lines vertically stacked on the second semiconductor layer C2 gradually increases, the number of the pass transistors of the row decoder 121 may also increase. Accordingly, sizes of the first and second decoder areas DEC1 and DEC2, which are required to place the row decoder 121, may increase.

According to the memory device 100, the length in the first direction X of the page buffer area PGBUF may be shorter than the length in the first direction X of the cell area CA to additionally secure the area in which the row decoder 121 is disposed. As an example, the length in the first direction X of the page buffer area PGBUF, i.e., D2, may be shorter than the length in the first direction X of the cell area CA, i.e., D1, as shown in FIG. 2.

In some implementations, the area occupied by the decoder areas DEC1 and DEC2 may expand along the first direction X. As an example, a length in the first direction X of the first decoder area DEC1 may extend by a length L1, and a length in the first direction X of the second decoder area DEC2 may extend by a length L2. Accordingly, when viewed in the horizontal direction, a portion of the first decoder area DEC1 may overlap the cell area CA, and a portion of the second decoder area DEC2 may overlap the cell area CA.

In some implementations, the row decoder 121 may be further disposed in an area overlapping the memory cell array 110 when viewed in the horizontal direction. Accordingly, the area to place the row decoder 121 may be further secured without increasing the chip size, and the overall chip size may be reduced.

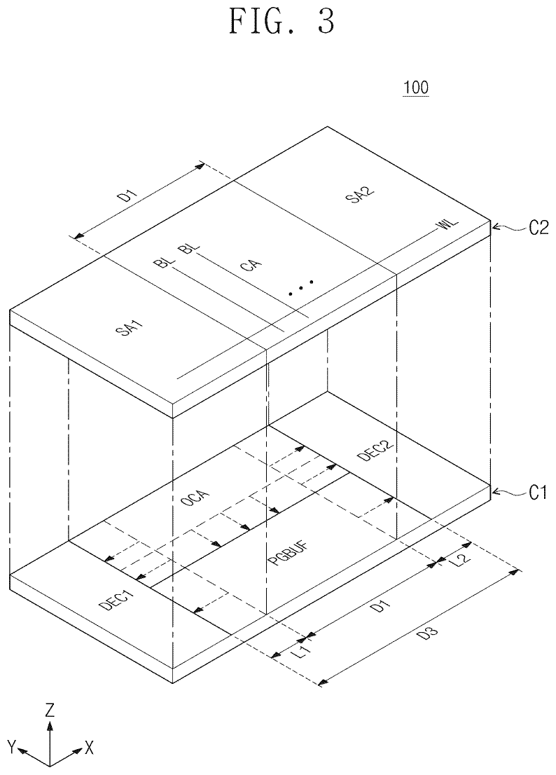

FIG. 3 is a layout illustrating an example arrangement of components of the memory device 100 of FIG. 1A according to some implementations. FIG. 3 shows a structure in which the length in the first direction X of the page buffer circuit 122 is longer than the length in the first direction X of the memory cell array 110. The arrangement of the components of the memory device 100 of FIG. 3 is similar to the arrangement of the components of the memory device 100 of FIG. 2. Accordingly, in FIG. 3, the same reference numerals denote the same elements in FIG. 2, and thus, detailed descriptions of the same elements will be omitted.

In FIG. 3, the memory device 100 may include the first and second semiconductor layers C1 and C2 vertically stacked in the vertical direction. The first semiconductor layer C1 may include the page buffer area PGBUF, the first and second decoder areas DEC1 and DEC2, and the other circuit area OCA. The second semiconductor layer C2 may include the cell area CA and the first and second step areas SA1 and SA2.

According to some implementations, a relatively large area may be required to place the peripheral circuit elements other than the row decoder 121. As an example, as functions performed by the control logic 123 become more advanced, the area occupied by the control logic 123 may increase, and the area occupied by the other circuit area OCA may increase.

According to the memory device 100, the length in the first direction X of the page buffer circuit 122 may be longer than the length in the first direction X of the memory cell array 110 to additionally secure the area in which the peripheral circuit elements such as the control logic 123 are disposed. As an example, one end and the other end of the page buffer area PGBUF may extend in the first direction X by lengths L1 and L2, respectively, and the length in the first direction X of the page buffer area PGBUF, i.e., D3, may be longer than the length in the first direction X of the cell area CA, i.e., D1.

As the length in the first direction X of the page buffer circuit 122 increases, the length in the second direction Y of the page buffer circuit 122 may decrease. As an example, circuit elements of the page buffer circuit 122 may be placed to correspond to the area of the page buffer circuit 122 expanded in the first direction X, and the length in the second direction Y of the page buffer circuit 122 may decrease.

Accordingly, the size of the other circuit area OCA in which the peripheral circuit elements, such as the control logic 123, are disposed may increase as shown in FIG. 3. Consequently, the size of the other circuit area OCA in which the control logic 123 is disposed may be further secured without increasing the chip size, and the overall chip size of the memory device 100 may be reduced.

FIG. 4 is a circuit diagram illustrating an example of a memory block among memory blocks included in the memory cell array 110 of FIG. 1A according to some implementations. In FIG. 4, a memory block BLKa may include a plurality of strings STR arranged in rows by columns. The strings STR may be commonly connected to a common source line CSL.

Each string may include at least one ground selection transistor GST connected to the ground selection line GSL, a plurality of memory cells MC1 to MC8 respectively connected to word lines WL1 to WL8, and string selection transistors SST respectively connected to string selection lines SSL1, SSL2, SSL3, and SSL4.

In each string, the ground selection transistor GST, the memory cells MC1 to MC8, and the string selection transistor SST may be connected in series along the third direction Z.

Each string may be connected to a corresponding bit line among first to fourth bit lines BL1 to BL4. The first to fourth bit lines BL1 to BL4 may extend in the second direction Y and may be arranged in the first direction X at regular intervals.

FIG. 4 shows a structure in which the common source line CSL is connected to lower ends of the strings STR. However, the common source line CSL is not limited to being physically located at the lower ends of the strings STR as long as the common source line CSL is electrically connected to the lower ends of the strings STR. As an example, FIG. 4 shows a structure in which the strings STR are arranged in four rows by four columns (4×4), however, the memory block BLKa may include fewer or more strings and bit lines.

According to some implementations, the bit lines BL1 to BL4 and the strings STR may be arranged in the cell area CA (refer to FIGS. 2 and 3). As described above, the length in the first direction X of the cell area CA may be different from the length in the first direction X of the page buffer area PGBUF (refer to FIGS. 2 and 3).

According to some implementations, the length in the first direction X of the cell area CA may be defined using a pitch between the bit lines arranged at regular intervals in the first direction X or a pitch between the strings arranged at regular intervals in the first direction X. As an example, when the number of the bit lines arranged in the first direction X is N and the pitch between the bit lines is S, the length in the first direction X of the cell area CA may be ‘(N−1)×S’ or may be defined as a length similar to the ‘(N−1)×S’.

FIG. 5 is a view illustrating an example of a row decoder of FIG. 1A according to some implementations. For the convenience of explanation, it is assumed that the string STR includes the ground selection transistor GST, the memory cells MC1 to MC8, and the string selection transistor SST, which are vertically stacked in the third direction Z similar to FIG. 4.

In FIG. 5, a row decoder 121 may include the pass transistors PT_GSL, PT1 to PT8, and PT_SSL. The pass transistors PT_GSL, PT1 to PT8, and PT_SSL may be disposed between the voltage generator 124 and the string STR. Each of the pass transistors PT_GSL, PT1 to PT8, and PT_SSL may apply a voltage generated by the voltage generator 124 to a corresponding row line among the row lines GSL, WL1 to WL8, and SSL connected to the string STR.

As described with reference to FIGS. 1 to 4, the row lines GSL, WL1 to WL8, and SSL may be formed in the second semiconductor layer C2 and may be vertically stacked in the third direction Z. The pass transistors PT_GSL, PT1 to PT8, and PT_SSL of the row decoder 121 may be formed in the first semiconductor layer C1 and may be disposed in one of the first and second decoder areas DEC1 and DEC2.

The number of stages of the row lines vertically stacked in the second semiconductor layer C2 along the third direction Z may increase due to a large capacity and a high degree of integration of the memory device. Accordingly, the number of the pass transistors of the row decoder 121 corresponding to the row lines, may also increase, and the first and second decoder areas DEC1 and DEC2 in which the row decoder 121 is disposed may increase.

According to some implementations, the length in the first direction X of the page buffer circuit 122 may be shorter than the length in the first direction X of the memory cell array 110. Accordingly, even though the number of stages of the row lines vertically stacked in the second semiconductor layer C2 increases, the memory device 100 may secure the area in which the row decoder 121 is disposed without increasing the chip size.

FIG. 6A is a view illustrating an example of a page buffer unit included in the page buffer circuit 122 of FIG. 1A according to some implementations. In FIG. 6A, a first page buffer unit 122_1 corresponding to the first bit line BL1 is shown. In addition, FIG. 6A shows a connection structure CS that electrically connects the bit line and the page buffer unit.

In FIG. 6A, the first page buffer unit 122_1 may include the high-voltage page buffer PB_HV and the low-voltage page buffer PB_LV. The high-voltage page buffer PB_HV may include a bit line selection transistor TR_BL. The bit line selection transistor TR_BL may be turned on in response to a bit line selection signal BLSLT and may connect the bit line BL to the low-voltage page buffer PB_LV. In this case, a voltage level of the bit line selection signal BLSLT may be a high voltage, and thus, the bit line selection transistor TR_BL may be implemented by the high-voltage transistor.

The low-voltage page buffer PB_LV may include a plurality of transistors TR_LV1 to TR_LVk and a plurality of latches LATCH 1 to LATCH n. As an example, the low-voltage page buffer PB_LV may store sensing results for the data stored in the memory cell during the read operation or may store the data to be programmed during the program operation. In this case, the transistors TR_LV1 to TR_LVK may be turned on in response to control signals CT1 to CTk at a low voltage level, respectively, and thus, the transistors TR_LV1 to TR_LVk may be implemented by the low-voltage transistor.

As described with reference to FIGS. 1 to 3, the first page buffer unit 122_1 may be disposed in the page buffer area PGBUF of the first semiconductor layer C1. The high-voltage page buffer PB_HV of the first page buffer unit 122_1 may be electrically connected to the first bit line BL1 disposed in the cell area CA of the second semiconductor layer C2.

In general, each page buffer unit may be disposed adjacent to a corresponding bit line. That is, when viewed in the horizontal direction, it is common that the page buffer unit and the bit line corresponding to the page buffer unit overlap with each other.

On the other hand, as described with reference to FIG. 2, the length in the first direction X of the page buffer circuit 122 may be shorter than the length in the first direction X of the memory cell array 110. In some implementations, some of the page buffer units of the page buffer circuit 122 may not overlap the corresponding bit line when viewed in the horizontal direction. As an example, when viewed in the horizontal direction, the first page buffer unit 122_1 may be disposed not to overlap the first bit line BL1 as shown in FIG. 6A.

According to the present disclosure, the memory device 100 (refer to FIG. 1A) may further include the connection structure CS to electrically connect the first page buffer unit 122_1 and the first bit line BL1, which do not overlap each other.

The connection structure CS may include a metal line that extends in the first direction X. As an example, the connection structure CS that connects the first bit line BL1 and the first page buffer unit 122_1 may include a first contact CT1, the metal line ML, and a second contact CT2, and the metal line ML may extend in the first direction X. Accordingly, when viewed in the horizontal direction, the first page buffer unit 122_1 and the first bit line BL1, which do not overlap each other, may be electrically connected to each other via the connection structure CS.

FIG. 6B is a view illustrating an example of a connection structure that electrically connects page buffer units included in the page buffer circuit 122 of FIG. 1A and bit lines according to some implementations.

As described with reference to FIG. 3, the length in the first direction X of the page buffer circuit 122 may be longer than the length in the first direction X of the memory cell array 110. In some implementations, the memory device 100 may further include the connection structure CS to electrically connect the page buffer units 122_1 to 122_n and the bit lines BL1 to BLn.

The connection structure CS may include a metal line that extends in the first direction X. As an example, the connection structure CS that connects a first bit line BL1 and a first page buffer unit 122_1 may include a first contact CT1, a metal line ML, and a second contact CT2, and the metal line ML may extend in the first direction X. Accordingly, even though the length in the first direction X of the page buffer circuit 122 is longer than the length in the first direction X of the memory cell array 110, the first bit line BL1 and the first page buffer unit 122_1 may be electrically connected to each other via the connection structure CS.

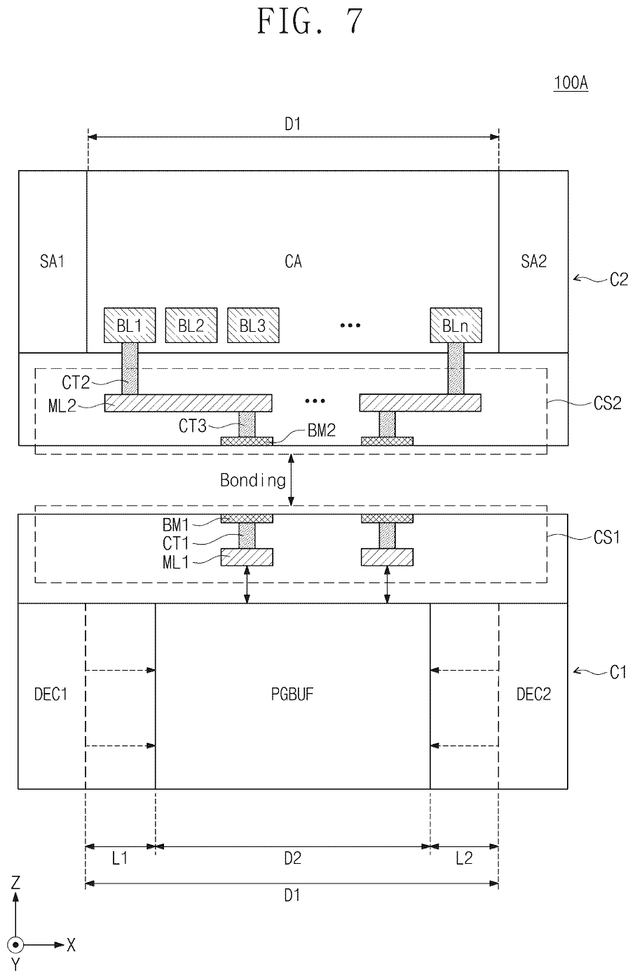

Meanwhile, the connection structure CS, as described with reference to FIGS. 6A and 6B, may be formed in the first semiconductor layer C1, may be formed in the second semiconductor layer C2, or may be formed in both the first and second semiconductor layers C1 and C2. Various embodiments about the connection structure CS will be described in detail with reference to FIGS. 7 to 19.

In FIGS. 1A to 6, the length in the first direction X of the page buffer circuit 122 may be different from the length in the first direction X of the memory cell array 110 in the memory device 100. Accordingly, the area to place the peripheral circuit element such as the row decoder 121 may be further secured without increasing the chip size. Consequently, the overall chip size of the memory device 100 may be reduced.

Hereinafter, in some implementations of the memory device, the length in the first direction X of the page buffer circuit 122 is different from the length in the first direction X of the memory cell array 110 will be described in detail.

In an example memory device, a length of a page buffer circuit is shorter than a length of a memory cell array.

FIG. 7 is a view illustrating an example of a memory device according to some implementations. FIG. 7 shows a structure in which a length in a first direction X of a page buffer circuit is shorter than a length in the first direction X of a memory cell array (refer to 110 of FIG. 1A). The memory device 100A of FIG. 7 is similar to the memory device 100 of FIGS. 1A to 6B. Accordingly, in FIG. 7, the same reference numerals denote the same elements in FIGS. 1A to 6B, and thus, detailed descriptions of the same elements will be omitted.

In FIG. 7, the memory device 100A may be implemented in a chip-to-chip (C2C) structure. As an example, a peripheral circuit (refer to 120 of FIG. 1A) may be formed in a first semiconductor layer C1, the memory cell array (refer to 110 of FIG. 1A) may be formed in a second semiconductor layer C2, and the first semiconductor layer C1 and the second semiconductor layer C2 may be coupled to each other by a bonding process. In this case, the second semiconductor layer C2 may be bonded to the first semiconductor layer C1 after being inverted. In the following descriptions, upper and lower portions of the second semiconductor layer C2 are defined based on the orientation of the second semiconductor layer C2 before being inverted.

First and second decoder areas DEC1 and DEC2 and a page buffer area PGBUF may be formed under the first semiconductor layer C1.

A length in the first direction X of the page buffer area PGBUF, i.e., D2, may be shorter than a length in the first direction X of a cell area CA, i.e., D1. Accordingly, a length in the first direction X of the first decoder area DEC1 may increase by a length L1. A portion of the first decoder area DEC1 may overlap the cell area CA. Similarly, a length in the first direction X of the second decoder area DEC2 may increase by a length L2. Accordingly, a portion of the second decoder area DEC2 may overlap the cell area CA.

A first connection structure CS1 may be formed at an upper portion of the first semiconductor layer C1. The first connection structure CS1 may include, for example, a first metal line ML1, a first bonding metal BM1, and a first contact CT1 that connects the first metal line ML1 and the first bonding metal BM1.

The first metal line ML1 and the first bonding metal BM1 may overlap each other when viewed in a horizontal direction. In addition, the first metal line ML1 and the first bonding metal BM1 may overlap the page buffer area PGBUF when viewed in the horizontal direction.

First and second step areas SA1 and SA2 and the cell area CA may be formed at a lower portion of the second semiconductor layer C2. A plurality of bit lines BL1 to BLn may be arranged at an upper portion of the cell area CA at regular intervals along the first direction X.

A second connection structure CS2 may be formed at an upper portion of the second semiconductor layer C2. The second connection structure CS2 may include, for example, a second metal line ML2, a second bonding metal BM2, and second and third contacts CT2 and CT3.

The second contact CT2 may electrically connect the second metal line ML2 and a first bit line BL1. The third contact CT3 may electrically connect the second metal line ML2 and the second bonding metal BM2.

The second bonding metal BM2 may be bonded to the first bonding metal BM1. The second bonding metal BM2 and the first bonding metal BM1 may overlap with each other when viewed in the horizontal direction.

Since the length in the first direction X of the page buffer area PGBUF, i.e., D2, is shorter than the length in the first direction X of the cell area CA, i.e., D1, some of the bit lines BL1 to BLn may not overlap the page buffer area PGBUF when viewed in the horizontal direction. As an example, the first bit line BL1 may not overlap the page buffer area PGBUF when viewed in the horizontal direction. In this case, the first bit line BL1 may not overlap a corresponding second bonding metal BM2.

The second metal line ML2 may extend in the first direction X to electrically connect the first bit line BL1 and the second bonding metal BM2, which do not overlap with each other. Accordingly, the first bit line BL1 may be electrically connected to the page buffer area PGBUF. Consequently, each of the bit lines BL1 to BLn disposed in the cell area CA may be electrically connected to a corresponding page buffer unit disposed in the page buffer area PGBUF via the second connection structure CS2.

In addition, since the length in the first direction X of the page buffer area PGBUF, i.e., D2, is shorter than the length in the first direction X of the cell area CA, i.e., D1, the first decoder area DEC1 and the second decoder area DEC2 may also expand along the first direction X.

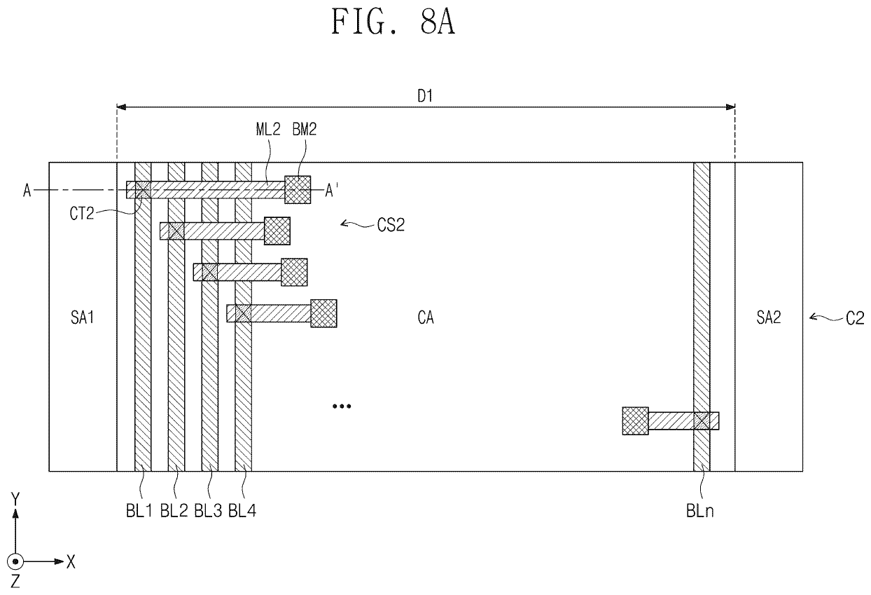

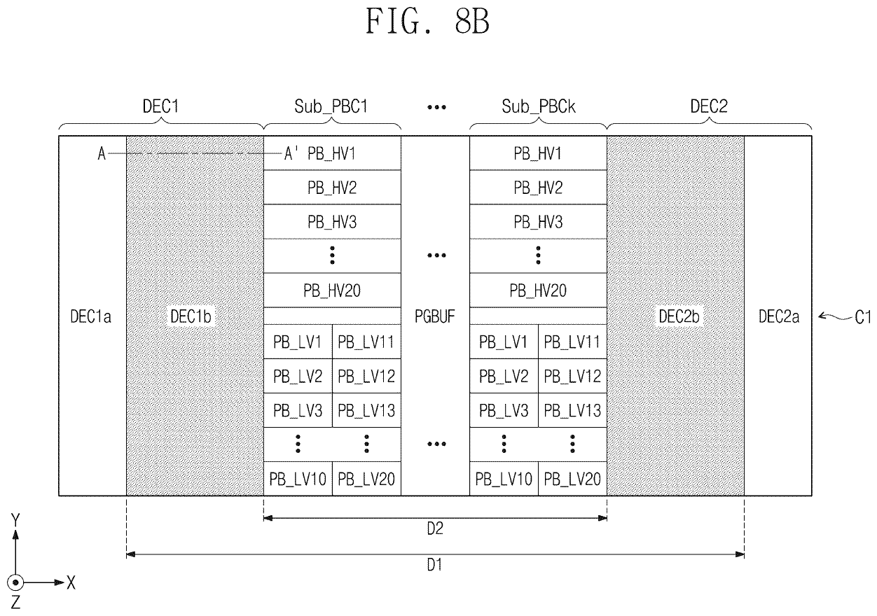

FIGS. 8A and 8B are views illustrating an example arrangement of components of the memory device 100A of FIG. 7 when viewed in the horizontal direction according to some implementations. For example, FIG. 8A shows the bit lines and the second connection structure CS2 disposed in the second semiconductor layer C2. FIG. 8B shows the page buffer circuit 122 disposed in the first semiconductor layer C1. For the convenience of explanation, FIG. 8A shows only the bit lines BL1 to BLn and the second connection structure CS2, and other circuit elements are omitted. FIG. 8B shows only a high-voltage page buffer and a low-voltage page buffer constituting the page buffer circuit 122, and other circuit elements are omitted.

In FIG. 8A, the second semiconductor layer C2 may include the first and second step areas SA1 and SA2 and the cell area CA. The bit lines BL1 to BLn may be disposed in the cell area CA. In detail, the bit lines BL1 to BLn may extend in the second direction Y and may be arranged at regular intervals in the first direction X.

The metal lines of the second connection structure CS2 may extend in the first direction X and may electrically connect the bit lines and page buffer units. As an example, the second metal line ML2 of the second connection structure CS2 may extend in the first direction X and may electrically connect the first bit line BL1 and the second bonding metal BM2. Accordingly, the first bit line BL1 may be electrically connected to a first high-voltage page buffer PB_HV1 (refer to FIG. 8B) of a first page buffer unit corresponding to the first bit line BL1.

In FIG. 8B, the first semiconductor layer C1 may include the first and second decoder areas DEC1 and DEC2 and the page buffer area PGBUF. The first decoder area DEC1 may include two decoder areas DEC1a and DEC1b. The decoder area DEC1a may overlap the first step area SA1 formed in the second semiconductor layer C2. The decoder area DEC1b may not overlap the first step area SA1 formed in the second semiconductor layer C2 and may overlap the cell area CA.

Similarly, the second decoder area DEC2 may include two decoder areas DEC2a and DEC2b. The decoder area DEC2a may overlap the second step area SA2 of the second semiconductor layer C2. The decoder area DEC2b may not overlap the second step area SA2 formed in the second semiconductor layer C2 and may overlap the cell area CA.

The page buffer circuit 122 (refer to FIG. 1A) may be disposed in the page buffer area PGBUF. The page buffer circuit 122 may include a plurality of sub-page buffer circuits Sub_PBC1 to Sub_PBCk. Each sub-page buffer circuit may be electrically connected to a predetermined number of bit lines and may include page buffer units corresponding to the predetermined number. Each page buffer unit may include the high-voltage page buffer and the low-voltage page buffer.

For the convenience of explanation, it is assumed that each sub-page buffer circuit is electrically connected to twenty bit lines. In some implementations, each sub-page buffer circuit may include twenty page buffer units, and each of the twenty page buffer units may include the high-voltage page buffer and the low-voltage page buffer. As an example, a first sub-page buffer circuit Sub_PBC1 may include first to twentieth high-voltage page buffers PB_HV1 to PB_HV20 and first to twentieth low-voltage page buffers PB_LV1 to PB_LV20, which are electrically connected to first to twentieth bit lines BL1 to BL20.

The high-voltage page buffer and the low-voltage page buffer corresponding to the high-voltage page buffer may constitute one page buffer unit. As an example, the first high-voltage page buffer PB_HV1 and the first low-voltage page buffer PB_LV1 may constitute the first page buffer unit, and the first page buffer unit may be electrically connected to the first bit line BL1. A second high-voltage page buffer PB_HV2 and a second low-voltage page buffer PB_LV2 may constitute a second page buffer unit, and the second page buffer unit may be electrically connected to a second bit line BL2.

The first to twentieth high-voltage page buffers PB_HV1 to PB_HV20 may be arranged in the page buffer area PGBUF along the second direction Y. The first to twentieth low-voltage page buffers PB_LV1 to PB_LV20 may be arranged in the page buffer area PGBUF along the first and second directions X and Y.

According to the present disclosure, the length in the first direction X of the page buffer area PGBUF, i.e., D2, may be shorter than the length in the first direction X of the cell area CA, i.e., D1. Accordingly, when viewed in the horizontal direction, pass transistors constituting a row decoder may be disposed in the decoder areas DEC1b and DEC2b overlapping the cell area CA.

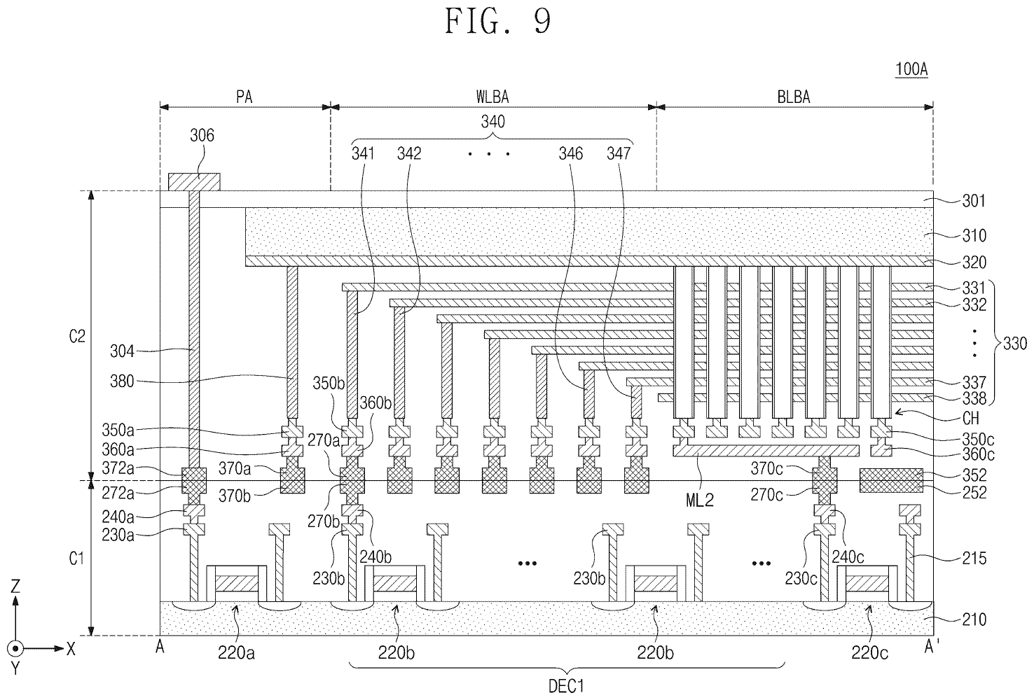

FIG. 9 is a cross-sectional view taken along a line A-A′ of FIGS. 8A and 8B according to some implementations. In FIGS. 8A, 8B, and 9, the memory device 100A may have the chip-to-chip (C2C) structure. For example, according to the memory device 100A, an upper chip including the second semiconductor layer C2 and a lower chip including the first semiconductor layer C1 may be respectively manufactured, and then, the upper chip may be connected to the lower chip by a bonding process after being inverted. As an example, the bonding process may mean a process of electrically bonding a bonding metal pattern formed in an uppermost metal layer of the upper chip to a bonding metal pattern formed in an uppermost metal layer of the lower chip. As an example, when the bonding metal patterns include copper (Cu), the bonding process may be a Cu-Cu bonding process. According to an embodiment, the bonding metal patterns may include aluminum (Al) or tungsten (W).

The memory device 100A may include at least one upper chip including the second semiconductor layer C2. As an example, the memory device 100A may include one upper chip as shown in FIGS. 8A to 9. However, this is merely an example, and the number of the upper chips should not be limited thereto or thereby. In the present disclosure, upper and lower portions of the upper chip are defined based on the orientation of the upper chip before being inverted. For example, an upper portion of the lower chip means an upper portion defined with respect to a +Z-axis direction, and the upper portion of the upper chip means an upper portion defined with respect to a −Z-axis direction.

The memory device 100A may include an external pad bonding area PA, a word line bonding area WLBA, and a bit line bonding area BLBA. In some implementations, the word line bonding area WLBA may correspond to the first step area SA1 of FIG. 8A. The bit line bonding area BLBA may correspond to the cell area CA of FIG. 8A.

The first semiconductor layer C1 may include a first substrate 210 and a plurality of circuit elements 220a, 220b, and 220c formed in the first substrate 210. An interlayer insulating layer 215 including one or more insulating layers may be provided on the circuit elements 220a, 220b, and 220c, and a plurality of metal lines may be provided in the interlayer insulating layer 215 to connect the circuit elements 220a, 220b, and 220c. As an example, the metal lines may include first metal lines 230a, 230b, and 230c respectively connected to the circuit elements 220a, 220b, and 220c and second metal lines 240a, 240b, and 240c formed on the first metal lines 230a, 230b, and 230c. The metal lines may include at least one of various conductive materials. As an example, the first metal lines 230a, 230b, and 230c may be formed of tungsten, which has a relatively high electrical resistivity, and the second metal lines 240a, 240b, and 240c may be formed of copper, which has a relatively low electrical resistivity.

In the present disclosure, only the first metal lines 230a, 230b, and 230c and the second metal lines 240a, 240b, and 240c are shown and described, however, the present disclosure should not be limited thereto or thereby. According to some implementations, one or more additional metal lines may be further formed on the second metal lines 240a, 240b, and 240c. For example, the second metal lines 240a, 240b, and 240c may be formed of aluminum. At least a portion of the additional metal lines formed on the second metal lines 240a, 240b, and 240c may be formed of copper that has an electrical resistivity lower than aluminum of the second metal lines 240a, 240b, and 240c.

The interlayer insulating layer 215 may be disposed on the first substrate 210 and may include an insulating material such as silicon oxide, silicon nitride, or the like.

The second semiconductor layer C2 may include a second substrate 310. The second substrate 310 may be formed of the same material as the first substrate 210. According to an embodiment, the second substrate 310 may be formed of a material different from the first substrate 210.

A common source line 320, which has a plate-like shape extending along the first direction X and the second direction Y, may be defined on the second substrate 310. The common source line CSL may include a metal material, e.g., tungsten (W), aluminum (Al), copper (Cu), tungsten nitride (WN), tantalum nitride (TaN), titanium nitride (TiN), or combinations thereof.

Word lines 330 (331 to 338) may be stacked on the second substrate 310 in the third direction Z vertical to an upper surface of the second substrate 310. String selection lines and a ground selection line may be disposed on and under the word lines 330, and the word lines 330 may be disposed between the string selection lines and the ground selection line.

A channel structure CH may extend in the third direction Z vertical to an upper surface of the common source line CSL and may penetrate the word lines 330, the string selection lines, and the ground selection line in the bit line bonding area BLBA. The channel structures CH may include a data storage layer, a channel layer, and a buried insulation layer, and the channel layer may be electrically connected to a first metal line 350c and a second metal line 360c. As an example, the first metal line 350c may be a bit line. The bit line 350c may be arranged at regular intervals in the first direction X.

In addition, an upper metal pattern 252 may be formed at an uppermost metal layer of the first semiconductor layer C1 in the bit line bonding area BLBA, and an upper metal pattern 352 having the same shape as the upper metal pattern 252 may be formed at an uppermost metal layer of the second semiconductor layer C2 in the bit line bonding area BLBA. The upper metal pattern 352 of the second semiconductor layer C2 may be electrically connected to the upper metal pattern 252 of the first semiconductor layer C1 by a bonding process.

In the bit line bonding area BLBA, the bit line 350c may be electrically connected to the page buffer of the first semiconductor layer C1. As an example, some of the circuit elements 220c of the first semiconductor layer C1 may provide the page buffer, and the bit line 350c may be electrically connected to the circuit elements 220c providing the page buffer via an upper bonding metal 370c of the second semiconductor layer C2 and an upper bonding metal 270c of the first semiconductor layer C1.

In FIGS. 8A, 8B, and 9, the word lines 330 of the second semiconductor layer C2 may extend in the second direction Y and may be connected to a plurality of cell contact plugs 340 (341 to 347) in the word line bonding area WLBA. A first metal line 350b and a second metal line 360b may be sequentially connected to upper portions of the cell contact plugs 340 connected to the word lines 330. In the word line bonding area WLBA, the cell contact plugs 340 may be connected to the first semiconductor layer C1 via an upper bonding metal 370b of the second semiconductor layer C2 and an upper bonding metal 270b of the first semiconductor layer C1.

The cell contact plugs 340 may be electrically connected to the row decoder of the first semiconductor layer C1. As an example, some of the circuit elements 220b of the first semiconductor layer C1 may provide the row decoder, and the cell contact plugs 340 may be electrically connected to the circuit elements 220b that provide the row decoder via the upper bonding metal 370b of the second semiconductor layer C2 and the upper bonding metal 270b of the first semiconductor layer C1.

In the external pad bonding area PA, common source line contact plugs 380 may be disposed on the common source line CSL of the second semiconductor layer C2 in the third direction Z vertical to an upper surface of the common source line CSL. The common source line contact plugs 380 may be formed of a conductive material, such as a metal, a metal compound, or doped polysilicon. The common source line contact plug 380 of the second semiconductor layer C2 may be electrically connected to the common source line CSL. A first metal line 350a and a second metal line 360a may be sequentially stacked on the common source line contact plug 380 of the second semiconductor layer C2. In addition, the common source line contact plug 380 may be connected to the first semiconductor layer C1 via an upper bonding metal 370a of the second semiconductor layer C2 and the upper bonding metal 270b of the first semiconductor layer C1.

In the external pad bonding area PA, a lower insulating layer 301 may be formed under the second substrate 310 to cover a lower surface of the second substrate 310, and an input/output pad 306 may be formed on the lower insulating layer 301. The input/output pad 306 may be connected to the circuit element 220a disposed in the first semiconductor layer C1 via an input/output contact plug 304.

According to the present disclosure, a portion of the second metal line 360c of the bit line bonding area BLBA may be provided as the second metal line ML2 described with reference to FIGS. 7 and 8A. For example, the second metal line ML2 may extend in the first direction X and may electrically connect the bit line 350c and the upper bonding metal 370c. Some of the bit lines 350c may not overlap the circuit element 220c provided as the page buffers and may overlap the circuit element 220b provided as the row decoders.

The length in the first direction X of the area in which the circuit elements 220c provided as the page buffer circuits are disposed may be shorter than the length in the first direction X of the area in which the bit lines 350c are disposed. Accordingly, the area to place the circuit element 220b provided as the row decoders may be further secured, and the overall chip size of the memory device 100A may be reduced.

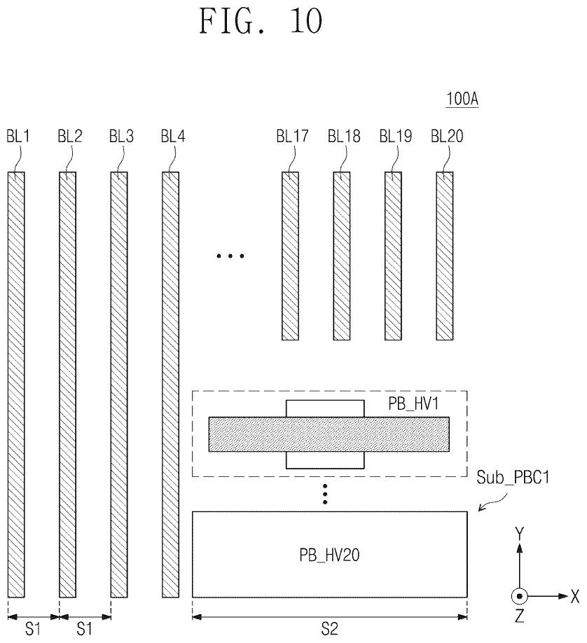

FIG. 10 is a view illustrating an example arrangement relationship between the bit lines and the sub-page buffer circuit of the memory device 100A of FIG. 7 according to some implementations. Similar to FIG. 8B, it is assumed that each sub-page buffer circuit of FIG. 10 is electrically connected to twenty bit lines. For the convenience of explanation, FIG. 10 shows only the high-voltage page buffers PB_HV1 to PB_HV20 among the high-voltage and low-voltage page buffers included in the first sub-page buffer circuit Sub_PBC1. In addition, portions of the bit lines BL17 to BL20, which overlap the high-voltage page buffers PB_HV1 to PB_HV20, are omitted.

In FIG. 10, each of the first to twentieth bit lines BL1 to BL20 may be electrically connected to a corresponding high-voltage page buffer among the first to twentieth high-voltage page buffers PB_HV1 to PB_HV20. As an example, the first bit line BL1 may be electrically connected to the first high-voltage page buffer PB_HV1, and the second bit line BL2 may be electrically connected to the second high-voltage page buffer PB_HV2.

Some of the first to twentieth bit lines BL1 to BL20 may not overlap the first to twentieth high-voltage page buffers PB_HV1 to PB_HV20 when viewed in the horizontal direction. As an example, the first to fourth bit lines BL1 to BL4 may not overlap the first to twentieth high-voltage page buffers PB_HV1 to PB_HV20. For example, the twenty high-voltage page buffers PB_HV1 to PB_HV20 arranged in the second direction Y may overlap sixteen bit lines BL5 to BL20. In some implementations, the number of stages of the page buffer units may be different from the number of the bit lines disposed within the pitch of the page buffer units.

In some implementations, the first to fourth bit lines BL1 to BL4 may be respectively connected to corresponding high-voltage page buffers PB_HV1 to PB_HV4 via the second connection structure CS2 (refer to FIG. 7). As an example, the second metal line ML2 (refer to FIG. 7) of the second connection structure CS2 may extend in the first direction X and may electrically connect the first bit line BL1 and the first high-voltage page buffer PB_HV1.

A distance between the bit lines adjacent to each other may be defined as a first pitch S1. In this case, the length in the first direction X of the cell area CA (refer to FIG. 8A) may be defined as a value obtained by multiplying the first pitch S1 by the number of the bit lines. As an example, when the number of the bit lines is ‘n’, the length in the first direction X of the cell area CA (refer to FIG. 8A), i.e., D1, may be defined by ‘S1×(n−1)’.

A length in the first direction X of the high-voltage page buffer may be defined as a second pitch S2. In this case, the length in the first direction X of the page buffer area PGBUF (refer to FIG. 8B) may be defined as a value obtained by multiplying the second pitch S2 by the number of the sub-page buffer circuits. As an example, when the number of the sub-page buffer circuits arranged in the first direction X is ‘k’, the length in the first direction X of the page buffer area PGBUF (refer to FIG. 8B), i.e., D2, may be defined by ‘S2×(k−1)’.

According to the memory device 100A of the present disclosure, the value of ‘S1×(n−1)’ corresponding to the length in the first direction X of the cell area CA may be greater than the value of ‘S2×(k−1)’ corresponding to the length in the first direction X of the page buffer area PGBUF.

In an example memory device, a connection structure is formed in a first semiconductor layer.

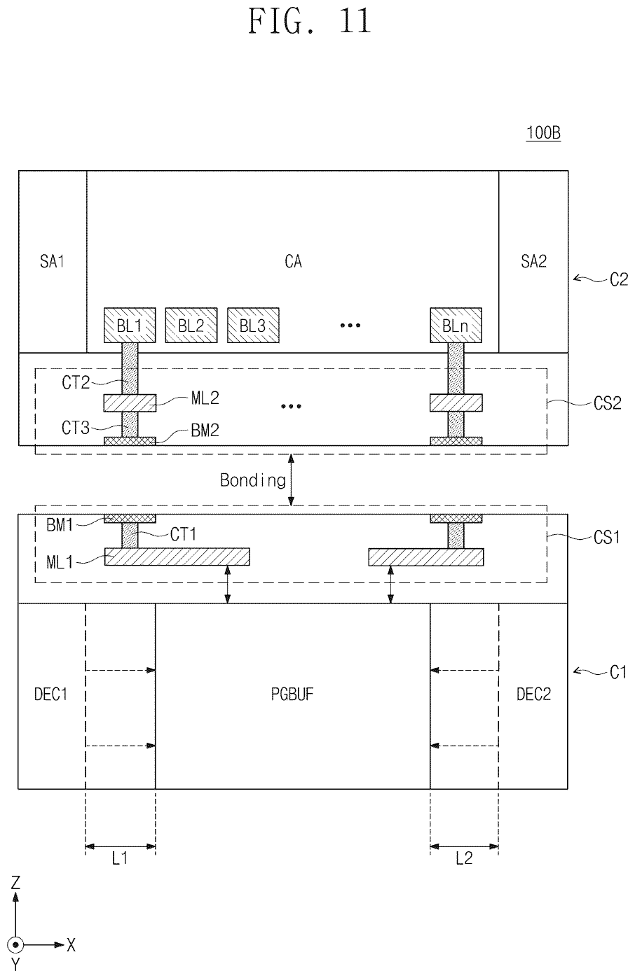

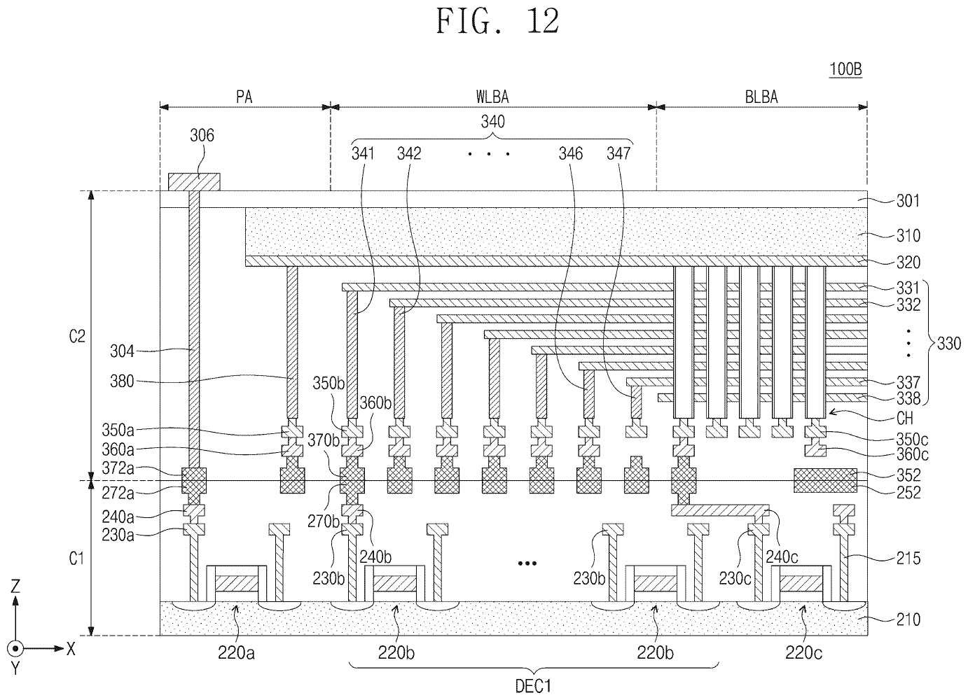

FIG. 11 is a view illustrating an example of a memory device according to some implementations. FIG. 12 is a cross-sectional view illustrating the memory device 100B of FIG. 11 according to some implementations. The memory device 100B of FIGS. 11 and 12 is similar to the memory device 100A described with reference to FIGS. 7 to 10. Accordingly, in FIGS. 11 and 12, the same reference numerals denote the same elements in FIGS. 7 to 10, and detailed descriptions of the same elements will be omitted.

In FIGS. 7 to 10, the second connection structure CS2 formed in the second semiconductor layer C2 is described to include the metal line extending in the first direction X. However, this is merely an example, and the present disclosure should not be limited thereto or thereby. As an example, a connection structure including a metal line extending in the first direction X may be formed in a first semiconductor layer C1 as shown in FIGS. 11 and 12.

In FIGS. 11 and 12, a second connection structure CS2 may be formed on a second semiconductor layer C2. The second connection structure CS2 may include, for example, a second metal line ML2, a second bonding metal BM2, and second and third contacts CT2 and CT3.

A first bit line BL1 may be connected to the second metal line ML2 via the second contact CT2, and the second metal line ML2 may be connected to the second bonding metal BM2 via the third contact CT3. When viewed in the horizontal direction, the first bit line BL1, the second metal line ML2, and the second bonding metal BM2 may overlap with each other.

A first connection structure CS1 may be formed at an upper portion of the first semiconductor layer C1. The first connection structure CS1 may include, for example, a first metal line ML1, a first bonding metal BM1, and a first contact CT1.

The first bonding metal BM1 may be bonded to the second bonding metal BM2. The second bonding metal BM2 may overlap the first bonding metal BM1 when viewed in the horizontal direction.

The first contact CT1 may electrically connect the first bonding metal BM1 and the first metal line ML1.

The first metal line ML1 may extend in the first direction X and may electrically connect the first bonding metal BM1 and a page buffer area PGBUF. For example, when viewed in the horizontal direction, the first bonding metal BM1 may overlap the first bit line BL1 but may not overlap the page buffer area PGBUF. The first metal line ML1 may extend in the first direction X and may electrically connect the first bonding metal BM1 that does not overlap the page buffer area PGBUF to the page buffer area PGBUF.

The first metal line ML1 of the first connection structure CS1 of FIG. 11 may correspond to a second metal line 240C formed in the first semiconductor layer C1 of FIG. 12.

According to the present disclosure, a first decoder area DEC1 and a second decoder area DEC2 may be expanded by lengths L1 and L2, respectively, and an area required to place a row decoder may be further secured. Consequently, the overall chip size of the memory device 100B may be reduced.

A memory device may include a COP structure.

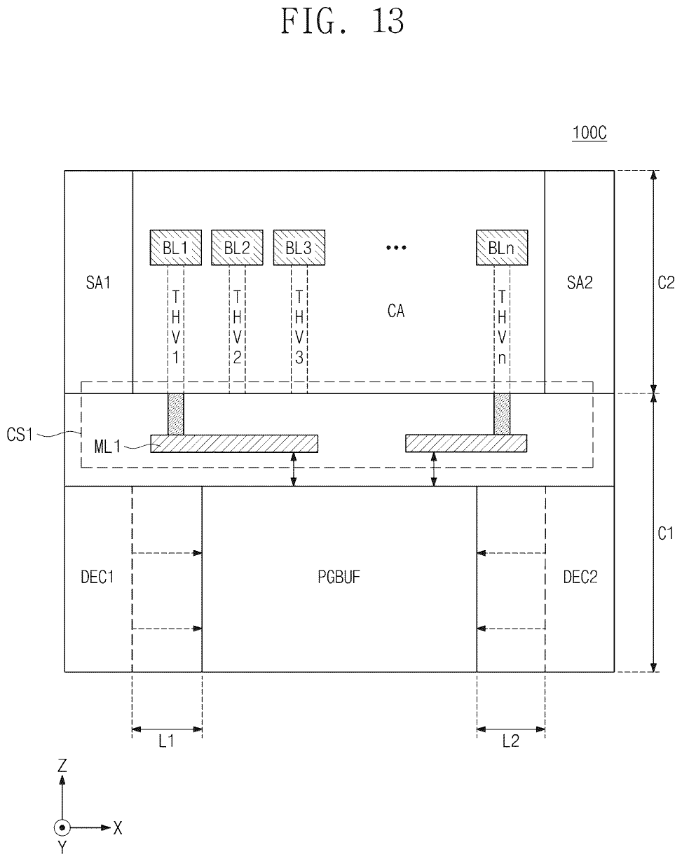

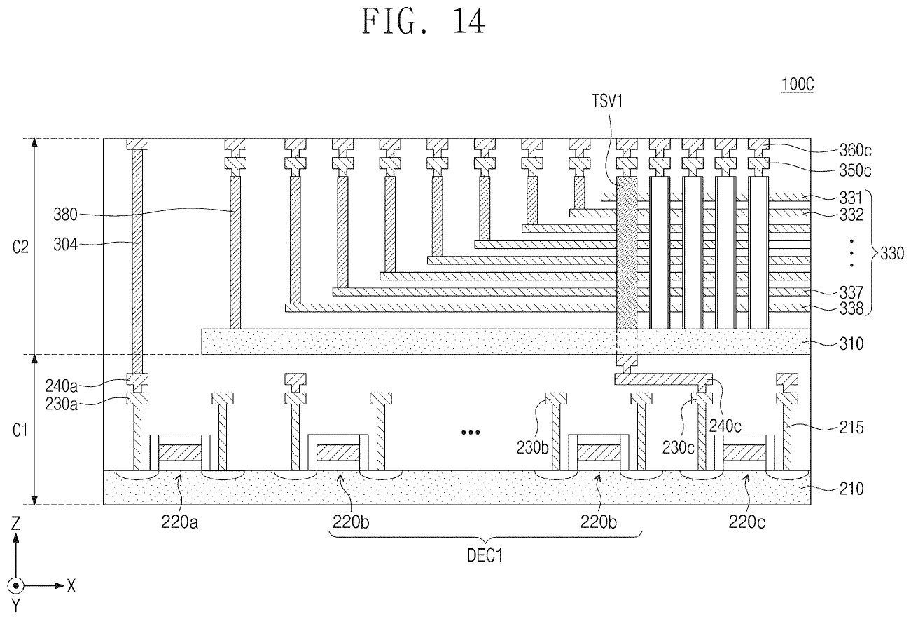

FIG. 13 is a view illustrating an example of a memory device according to some implementations. FIG. 14 is a cross-sectional view illustrating the memory device 100C of FIG. 13 according to some implementations. The memory device 100C of FIGS. 13 and 14 is similar to the memory devices 100A and 100B described with reference to FIGS. 7 to 12. Accordingly, in FIGS. 13 and 14, the same reference numerals denote the same elements in FIGS. 7 to 12, and detailed descriptions of the same elements will be omitted.

In FIGS. 7 to 12, the memory devices 100A and 100B are described to have the C2C structure. However, this is merely an example, and the present disclosure should not be limited thereto or thereby. As an example, the memory device 100C according to the present embodiment may have the COP structure as shown in FIGS. 13 and 14.

In FIG. 13, a second semiconductor layer C2 may be stacked on a first semiconductor layer C1. The second semiconductor layer C2 may include step areas SA1 and SA2 and a cell area CA. Bit lines BL1 to BLn may be disposed at an upper portion of the cell area CA. Each of the bit lines BL1 to BLn may be connected to the first semiconductor layer C1 through a corresponding through via. As an example, a first bit line BL1 may be connected to the first semiconductor layer C1 via a first through via THV1. According to some implementations, a through metal pattern may be formed in a second substrate 310 to electrically connect the first through via THV1 and a first connection structure CS1.

The first connection structure CS1 may be formed at an upper portion of the first semiconductor layer C1. The first connection structure CS1 may include, for example, first metal lines ML1 extending in the first direction X.

At least one of the first metal lines ML1 may extend in the first direction X and may electrically connect the bit line and a page buffer area PGBUF. As an example, the first metal line ML1 corresponding to the first bit line BL1 may extend in the first direction X and may electrically connect the first through via THV1 and the page buffer area PGBUF. Accordingly, the first bit line BL1 that does not overlap the page buffer area PGBUF may be electrically connected to the page buffer area PGBUF via the first through via THV1 and the first metal line ML1.

According to the present disclosure, a first decoder area DEC1 and a second decoder area DEC2 may be expanded by lengths L1 and L2, respectively, and an area required to place a row decoder may be further secured. Consequently, the overall chip size of the memory device 100C may be reduced.

A memory device may have a length of a page buffer circuit is longer than a length of a memory cell array.

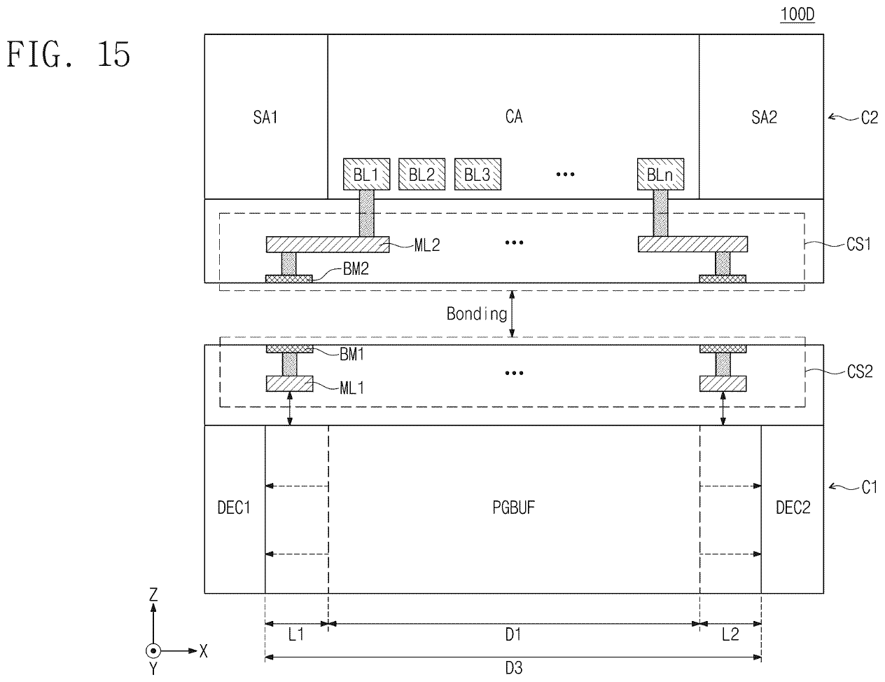

FIG. 15 is a view illustrating an example of a memory device according to some implementations. The memory device 100D of FIG. 15 is similar to the memory devices 100A, 100B, and 100C described with reference to FIGS. 7 to 14. Accordingly, in FIG. 15, the same reference numerals in denote the same elements in FIGS. 7 to 14, and detailed descriptions of the same elements will be omitted.

In FIGS. 7 to 14, the length in the first direction X of the page buffer area PGBUF is described to be shorter than the length in the first direction X of the cell area CA. However, this is merely an example, and the present disclosure should not be limited thereto or thereby. As an example, a length in the first direction X of a page buffer area PGBUF, i.e., D3, may be longer than a length in the first direction X of a cell area CA, i.e., D1, as shown in FIG. 15.

Referring to FIG. 15, a first semiconductor layer C1 may include first and second decoder areas DEC1 and DEC2 and the page buffer area PGBUF.

The length in the first direction X of the page buffer area PGBUF, i.e., D3, may be longer than the length in the first direction X of the cell area CA, i.e., D1. Accordingly, a length in the first direction X of the first decoder area DEC1 may decrease by a length L1. A portion of a first step area SA1 may overlap the page buffer area PGBUF.

Similarly, a length in the first direction X of the second decoder area DEC2 may decrease by a length L2. A portion of a second step area SA2 may overlap the page buffer area PGBUF.

A first connection structure CS1 may be formed at an upper portion of the first semiconductor layer C1. The first connection structure CS1 may include a first metal line ML1 and a first bonding metal BM1, and the first metal line ML1 may overlap the first bonding metal BM1 when viewed in the horizontal direction.

A second semiconductor layer C2 may include the first and second step areas SA1 and SA2 and the cell area CA. A plurality of bit lines BL1 to BLn may be arranged in the first direction X at regular intervals at an upper portion of the cell area CA.

A second connection structure CS2 may be formed at an upper portion of the second semiconductor layer C2. The second connection structure CS2 may include a second metal line ML2 and a second bonding metal BM2, and the second metal line ML2 may extend in the first direction X.

Since the length in the first direction X of the page buffer area PGBUF, i.e., D3, is longer than the length in the first direction X of the cell area CA, i.e., D1, a portion of the page buffer area PGBUF may not overlap the cell area CA. As an example, a circuit element disposed at a leftmost position in the page buffer area PGBUF, for example, a high-voltage page buffer, may overlap the first step area SA1 rather than the cell area CA.

In some implementations, the second metal line ML2 may extend in the first direction X to electrically connect the circuit element disposed at the leftmost position in the page buffer area PGBUF to a first bit line BL1 of the cell area CA.

Meanwhile, as described with reference to FIG. 3, when the length in the first direction X of the page buffer area PGBUF increases, the length in the second direction Y of the page buffer area PGBUF may be shorter than a conventional case. Accordingly, the size of the other circuit area OCA (refer to FIG. 3) may be expanded, and an area to place a circuit element such as a control logic may be further secured without increasing the overall chip size.

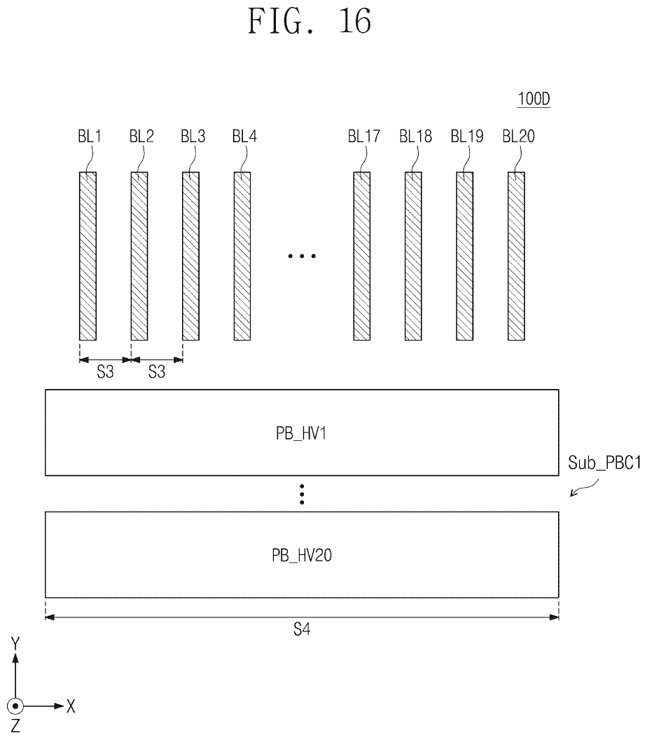

FIG. 16 is a view illustrating an example arrangement relationship between the bit lines and a sub-page buffer circuit of the memory device of FIG. 15 according to some implementations. For the convenience of explanation, similar to FIG. 10, it is assumed that each sub-page buffer circuit is electrically connected to twenty bit lines. In addition, similar to FIG. 10, FIG. 16 shows only high-voltage page buffers PB_HV1 to PB_HV20 among high-voltage and low-voltage page buffers included in a first sub-page buffer circuit Sub_PBC1, and portions of the bit lines BL1 to BL20, which overlap the high-voltage page buffers PB_HV1 to PB_HV20, are omitted.

In FIG. 16, each of first to twentieth bit lines BL1 to BL20 may be electrically connected to a corresponding high-voltage page buffer among first to twentieth high-voltage page buffers PB_HV1 to PB_HV20.

A distance between the bit lines may be defined as a third pitch S3. In this case, the length in the first direction X of the cell area CA (refer to FIG. 15) may be defined as a value obtained by multiplying the third pitch S3 by the number of the bit lines. As an example, when the number of the bit lines is ‘n’, the length in the first direction X of the cell area CA may be defined by ‘S3×(n−1)’.

A length in the first direction X of the high-voltage page buffer may be defined as a fourth pitch S4. In this case, the length in the first direction X of the page buffer area PGBUF (refer to FIG. 15) may be defined as a value obtained by multiplying the fourth pitch S4 by the number of the sub-page buffer circuits. As an example, when the number of the sub-page buffer circuits arranged in the first direction X is ‘k’, the length in the first direction X of the page buffer area PGBUF may be defined by ‘S4×(k−1)’.

According to the memory device 100D of the present disclosure, the value of ‘S3×(n−1)’ corresponding to the length in the first direction X of the cell area CA may be smaller than the value of ‘S4×(k−1)’ corresponding to the length in the first direction X of the page buffer area PGBUF.

Meanwhile, the above-described implementations are merely an example, and it will be understood that the inventive concept of the present disclosure should not be limited thereto or thereby.

As an example, the memory device 100D shown in FIGS. 15 and 16 has the C2C structure. However, this is merely an example, and the present disclosure should not be limited thereto or thereby. As an example, the memory device having the COP structure described with reference to FIGS. 13 and 14 may also be implemented to allow the length in the first direction X of the page buffer circuit to be longer than the length in the first direction X of the memory cell array.

In addition, as an example, in FIGS. 7 to 14, the portion of the first decoder area DEC1 and the portion of the second decoder area DEC2 overlap the cell area CA. However, this is merely an example, and the areas additionally secured by the length of the page buffer area PGBUF that is shortened may be arranged in various ways. Hereinafter, various implementations of the page buffer area PGBUF and the decoder area DEC will be described in more detail.

Various arrangements of a page buffer area and a decoder area may be provided.

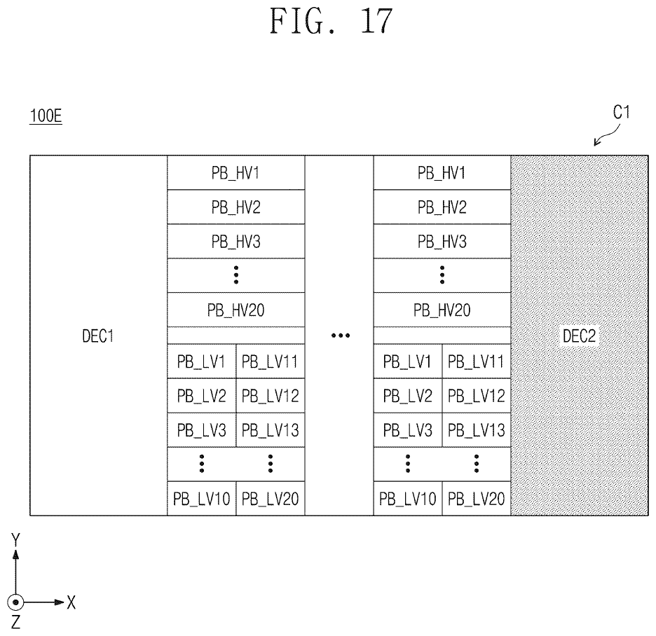

FIGS. 17 to 19 are views illustrating examples of arrangements of a page buffer area and a decoder area according to some implementations, which are formed in a first semiconductor layer C1. The first semiconductor layer C1 of each of FIGS. 17 to 19 is similar to the first semiconductor layer C1 of FIG. 8B. Accordingly, in FIGS. 17 to 19, the same reference numerals denote the same elements in FIG. 8B, and detailed descriptions of the same elements will be omitted.

In FIG. 17, in a memory device 100E, the first semiconductor layer C1 may be implemented such that only one decoder area of two decoder areas DEC1 and DEC2 overlaps a cell area (refer to CA of FIG. 8A). As an example, a first decoder area DEC1 may overlap only a first step area (refer to SA1 of FIG. 8A) and may not overlap the cell area CA. A second decoder area DEC2 may entirely overlap the cell area CA.

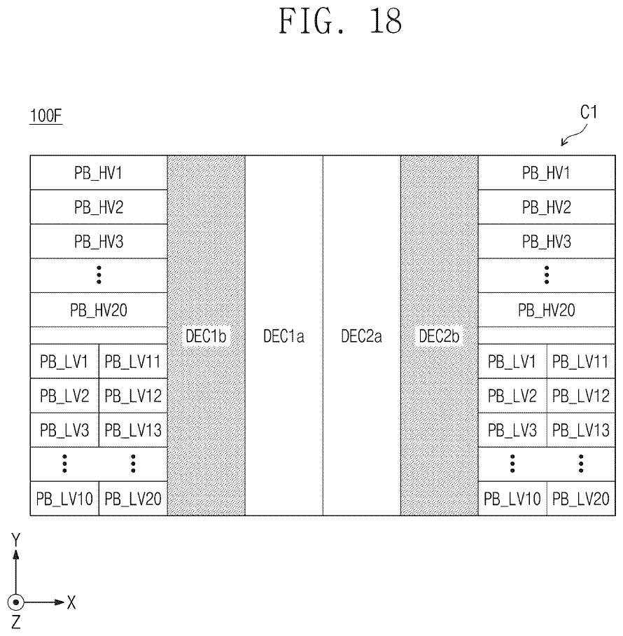

In FIG. 18,, in a memory device 100F, first decoder areas DEC1a and DEC1b and second decoder areas DEC2a and DEC2b may be formed inside the first semiconductor layer C1. As an example, the first decoder areas DEC1a and DEC1b and the second decoder areas DEC2a and DEC2b may be formed inside the first semiconductor layer C1, and the page buffer area PGBUF may be formed outside the first semiconductor layer C1. In some implementations, a portion, e.g., the first decoder area DEC1b, of the first decoder areas DEC1a and DEC1b may overlap a cell area (refer to CA of FIG. 8A), and a portion, e.g., the second decoder area DEC2b, of the second decoder areas DEC2a and DEC2b may overlap the cell area CA.

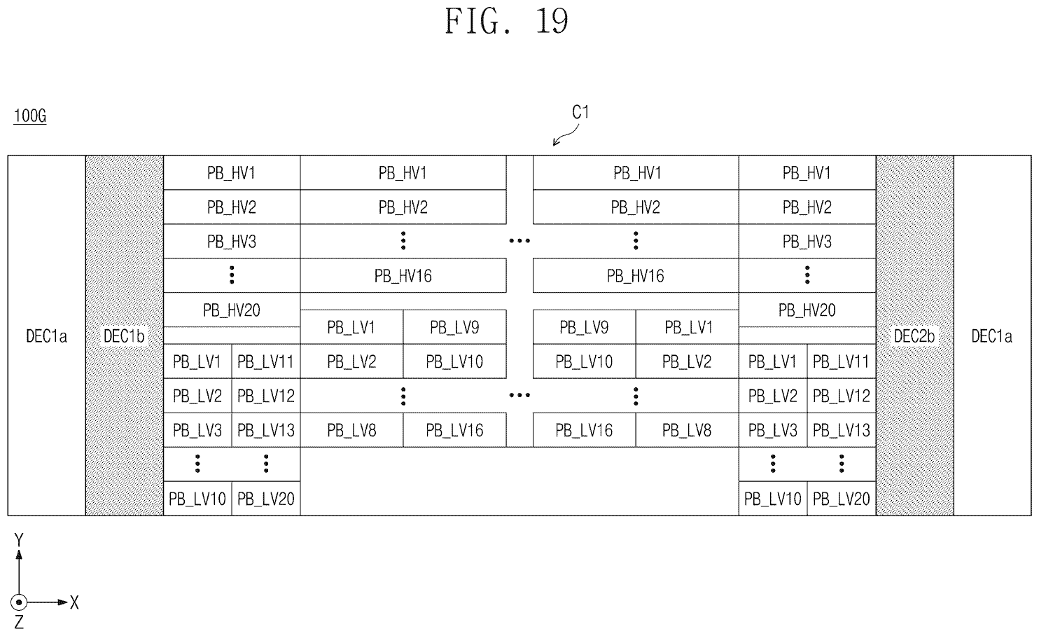

In FIG. 19, in a memory device 100G, a plurality of sub-page buffer circuits is disposed in the first semiconductor layer C1, sub-page buffer circuits may be disposed at a relatively inside position of the first semiconductor layer C1, and the sub-page buffer circuits according to the present disclosure may be disposed at a relatively outside position of the first semiconductor layer C1. As an example, the sub-page buffer circuit disposed at the relatively inside position of the first semiconductor layer C1 may be electrically connected to sixteen bit lines, and the sub-page buffer circuit disposed at the relatively outside position of the first semiconductor layer C1 may be electrically connected to twenty bit lines.

In some implementations, a portion, i.e., a first decoder area DEC1b, of first decoder areas DEC1a and DEC1b may overlap a cell area (refer to CA of FIG. 8A), and a portion, i.e., a second decoder area DEC2a, of second decoder areas DEC2a and DEC2b may overlap the cell area CA. Various implementations of the C2C structure may be employed.

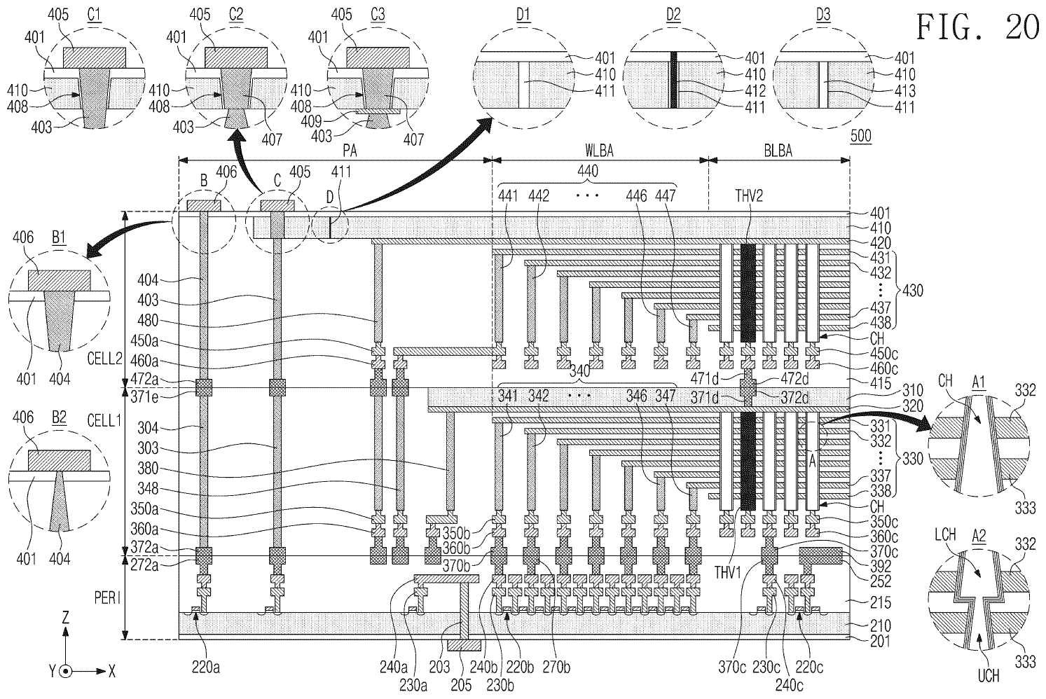

FIG. 20 is a cross-sectional view illustrating an example of a memory device according to some implementations. For the convenience of explanation, in FIG. 20, various structures that are changeable and applicable to a memory device according to implementations of the present disclosure are comprehensively illustrated.

For the convenience of explanation, it is assumed that two semiconductor layers C2 and C3 in each of which a memory cell array is formed are connected to one semiconductor layer in which a peripheral circuit is formed by a bonding process in the memory device 100H of FIG. 20. In addition, in the following descriptions, a first semiconductor layer C1 may be referred to as a peripheral circuit area PERI, and second and third semiconductor layers C2 and C3 may be referred to as first and second cell areas CELL1 and CELL2, respectively.

In FIG. 20, the memory device 100H may have a chip-to-chip (C2C) structure. In some implementations, the C2C structure may be obtained by manufacturing at least one upper chip including a cell area and a lower chip including the peripheral circuit area PERI and connecting the upper chip and the lower chip by a bonding process. As an example, the bonding process may indicate a process of electrically connecting a bonding metal formed at a top metal layer of the upper chip and a bonding metal formed at a top metal layer of the lower chip. As an example, when the bonding metals are formed of copper (Cu), the bonding process may be a Cu-Cu bonding process. According to some implementations, the bonding metals may be formed of aluminum (Al) or tungsten (W).

The memory device 100H may include at least one upper chip including the cell area. As an example, the memory device 100H may include two upper chips as shown in FIG. 20. However, this is merely an example, and the number of the upper chips should not be limited thereto or thereby. When the memory device 100H includes two upper chips, the memory device 100H may be manufactured by forming a first upper chip including the first cell area CELL1, a second upper chip including the second cell area CELL2, and the lower chip including the peripheral circuit area PERI and connecting the first upper chip, the second upper chip, and the lower chip by the bonding process. The first upper chip may be connected to the lower chip by the bonding process after being inverted, and the second upper chip may be connected to the first upper chip by the bonding process after being inverted. In the following descriptions, upper and lower portions of the first and second upper chips are defined based on the orientation of the first and second upper chips before being inverted. For example, in FIG. 20, the upper portion of the lower chip indicates a +Z-axis direction, and the upper portion of the first and second upper chips indicates a −Z-axis direction, however, this is merely an example. According to some implementations, only one of the first and second upper chips may be reversed and may be connected by the bonding process.

In the memory device 100H, each of the peripheral circuit area PERI and the first and second cell areas CELL1 and CELL2 may include an external pad bonding area PA, a word line bonding area WLBA, and a bit line bonding area BLBA.

The peripheral circuit area PERI may include a first substrate 210 and a plurality of circuit elements 220a, 220b, and 220c formed on the first substrate 210. At least one interlayer insulating layer 215 may be provided on the circuit elements 220a, 220b, and 220c, and a plurality of metal lines may be provided on the interlayer insulating layer 115 to connect the circuit elements 220a, 220b, and 220c. As an example, the metal lines may include first metal lines 230a, 230b, and 230c respectively connected to the circuit elements 220a, 220b, and 220c and second metal lines 240a, 240b, and 240c respectively disposed on the first metal lines 230a, 230b, and 230c. The metal lines may include various conductive materials. As an example, the first metal lines 230a, 230b, and 230c may be formed of tungsten, which has a relatively high electrical resistivity, and the second metal lines 240a, 240b, and 240c may be formed of copper, which has a relatively low electrical resistivity.

In the present disclosure, only the first metal lines 230a, 230b, and 230c and the second metal lines 240a, 240b, and 240c are shown and described, however, the present disclosure should not be limited thereto or thereby. According to some implementations, one or more metal lines may be further formed on the second metal lines 240a, 240b, and 240c. For example, the second metal lines 240a, 240b, and 240c may be formed of aluminum. At least a portion of the one or more metal lines formed on the second metal lines 240a, 240b, and 240c may be formed of copper that has an electrical resistivity lower than aluminum of the second metal lines 240a, 240b, and 240c.

The interlayer insulating layer 215 may be disposed on the first substrate 210 and may include an insulating material such as silicon oxide, silicon nitride, or the like.

Each of the first and second cell areas CELL1 and CELL2 may include at least one memory block. The first cell area CELL1 may include a second substrate 310 and a common source line 320. A plurality of word lines 330 (331 to 338) may be stacked on the second substrate 310 in a direction (e.g., the Z-axis direction) vertical to an upper surface of the second substrate 310. String selection lines and a ground selection line may be disposed on and under the word lines 330, respectively, and the word lines 330 may be disposed between the string selection lines and the ground selection line. Similarly, the second cell area CELL2 may include a third substrate 410 and a common source line 420, and a plurality of word lines 430 (431 to 438) may be stacked on the third substrate 410 in the direction (e.g., the Z-axis direction) vertical to an upper surface of the third substrate 410. The second substrate 310 and the third substrate 410 may include various materials and may be a silicon substrate, a silicon-germanium substrate, a germanium substrate, or a substrate including a monocrystalline epitaxial layer grown on a monocrystalline silicon substrate. A plurality of channel structures CH may be formed in each of the first and second cell areas CELL1 and CELL2.

According to some implementations, as shown in an area A1, a channel structure CH may be provided in a bit line bonding area BLBA and may extend in a direction vertical to an upper surface of a second substrate 310 to penetrate word lines 330, string selection lines, and a ground selection line. The channel structure CH may include a data storage layer, a channel layer, and a buried insulation layer. The channel layer may be electrically connected to a first metal line 350c and a second metal line 360c in the bit line bonding area BLBA. As an example, the first metal line 350c may be a bit line and may be connected to the channel structure CH. According to some implementations, the second metal line 360c may be a bit line and may be connected to the channel structure CH through the first metal line 350c. The bit line may extend in Y-axis direction substantially parallel to the upper surface of the second substrate 310.

According to some implementations, as shown in an area A2, a channel structure CH may include a lower channel LCH and an upper channel UCH connected to the lower channel LCH. As an example, the channel structure CH may be formed through a process for the lower channel LCH and a process for the upper channel UCH. The lower channel LCH may extend in a direction vertical to an upper surface of a second substrate 310 and may penetrate a common source line 320 and lower word lines 331 and 332. The lower channel LCH may include a data storage layer, a channel layer, and a buried insulation layer and may be connected to the upper channel UCH. The upper channel UCH may penetrate upper word lines 333 to 338. The upper channel UCH may include a data storage layer, a channel layer, and a buried insulation layer, and the channel layer of the upper channel UCH may be electrically connected to a first metal line 350c and a second metal line 360c. As a length of the channel increases, it becomes more difficult to form the channel with a uniform width due to process-related reasons. The memory device 100H according to the present embodiment may have a channel with improved width uniformity through the lower channel LCH and the upper channel UCH, which are formed through sequential processes.

As shown in the area A2, when the channel structure CH includes the lower channel LCH and the upper channel UCH, a word line located near a boundary between the lower channel LCH and the upper channel UCH may be a dummy word line. As an example, a word line 332 and a word line 333, which form the boundary between the lower channel LCH and the upper channel UCH may be the dummy word line. In some implementations, data may not be stored in memory cells connected to the dummy word line. The number of pages corresponding to the memory cells connected to the dummy word line may be smaller than the number of pages corresponding to memory cells connected to a normal word line. A level of a voltage applied to the dummy word line may be different from a level of a voltage applied to the normal word line, and thus, influences of uneven channel width between the lower channel LCH and the upper channel UCH on the operation of the memory device may be reduced.

Meanwhile, in the area A2, the number of the lower word lines 331 and 332 through which the lower channel LCH penetrates is smaller than the number of the upper word lines 333 to 338 through which the upper channel UCH penetrates. However, this is merely an example, and the present disclosure should not be limited thereto or thereby. According to some implementations, the number of the lower word lines through which the lower channel LCH penetrates may be equal to or greater than the number of the upper word lines through which the upper channel UCH penetrates. In addition, the structure and connection relationship of the channel structure CH disposed in a first cell area CELL1 described above may be equally applied to a channel structure CH disposed in a second cell area CELL2.

In the bit line bonding area BLBA, a first through via THV1 may be provided in the first cell area CELL1, and a second through via THV2 may be provided in the second cell area CELL2. As shown in FIG. 20, the first through via THV1 may penetrate the common source line 320 and the word lines 330, however, this is merely an example, and the first through via THV1 may further penetrate the second substrate 310. The first through via THV1 may include a conductive material. According to some implementations, the first through via THV1 may include a conductive material surrounded by an insulating material. The second through via THV2 may have substantially the same shape and structure as those of the first through via THV1.

The first through via THV1 and the second through via THV2 may be electrically connected to each other through a first through metal pattern 372d and a second through metal pattern 472d. The first through metal pattern 372d may be formed at a lower end of the first upper chip including the first cell area CELL1, and the second through metal pattern 472d may be formed at an upper end of the second upper chip including the second cell area CELL2. The first through via THV1 may be electrically connected to the first metal line 350c and the second metal line 360c. A lower via 371d may be formed between the first through via THV1 and the first through metal pattern 372d, and an upper via 471d may be formed between the second through via THV2 and the second through metal pattern 472d. The first through metal pattern 372d may be connected to the second through metal pattern 472d by a bonding process.

In addition, in the bit line bonding area BLBA, an upper metal pattern 252 may be formed at a top metal layer of the peripheral circuit area PERI, and an upper metal pattern 392 having the same shape as the upper metal pattern 252 may be formed at a top metal layer of the first cell area CELL1. The upper metal pattern 392 of the first cell area CELL1 may be electrically connected to the upper metal pattern 252 of the peripheral circuit area PERI by a bonding process. In the bit line bonding area BLBA, the bit line 350c or 360c may be electrically connected to a page buffer included in the peripheral circuit area PERI. As an example, some of the circuit elements 220c of the peripheral circuit area PERI may provide a page buffer, and the bit line 350c or 360c may be electrically connected to the circuit elements 220c providing the page buffer through an upper bonding metal 370c of the first cell area CELL1 and an upper bonding metal 270c of the peripheral circuit area PERI.

In FIG. 20, in the word line bonding area WLBA, the word lines 330 of the first cell area CELL1 may extend in an X-axis direction substantially parallel to the upper surface of the second substrate 310 and may be connected to a plurality of cell contact plugs 340 (341 to 347). A first metal line 350b and a second metal line 360b may be sequentially connected to an upper portion of the cell contact plugs 340 connected to the word lines 330. In the word line bonding area WLBA, the cell contact plugs 340 may be connected to the peripheral circuit area PERI through an upper bonding metal 370b of the first cell area CELL1 and an upper bonding metal 270b of the peripheral circuit area PERI.

The cell contact plugs 340 may be electrically connected to a row decoder included in the peripheral circuit area PERI. As an example, some of the circuit elements 220b of the peripheral circuit area PERI may provide a row decoder, and the cell contact plugs 340 may be electrically connected to the circuit elements 220b providing the row decoder through the upper bonding metal 370b of the first cell area CELL1 and the upper bonding metal 270b of the peripheral circuit area PERI. According to an embodiment, an operation voltage of the circuit elements 220b providing the row decoder may be different from an operation voltage of the circuit elements 220c providing the page buffer. As an example, the operation voltage of the circuit elements 220c providing the page buffer may be greater than the operation voltage of the circuit elements 220b providing the row decoder.

Similarly, in the word line bonding area WLBA, the word lines 430 of the second cell area CELL2 may extend in the X-axis direction substantially parallel to the upper surface of the third substrate 410 and may be connected to a plurality of cell contact plugs 440 (441 to 447). The cell contact plugs 440 may be connected to the peripheral circuit area PERI through the upper metal pattern of the second cell area CELL2, the lower metal pattern and the upper metal pattern of the first cell area CELL1, and a cell contact plug 348.

In the word line bonding area WLBA, the upper bonding metal 370b may be formed in the first cell area CELL1, and the upper bonding metal 270b may be formed in the peripheral circuit area PERI. The upper bonding metal 370b of the first cell area CELL1 may be electrically connected to the upper bonding metal 270b of the peripheral circuit area PERI by a bonding process. The upper bonding metal 370b and the upper bonding metal 270b may be formed of aluminum, copper, or tungsten.

In the external pad bonding area PA, a lower metal pattern 371e may be formed at a lower portion of the first cell area CELL1, and an upper metal pattern 472a may be formed at an upper portion of the second cell area CELL2. The lower metal pattern 371e of the first cell area CELL1 and the upper metal pattern 472a of the second cell area CELL2 may be connected to each other by a bonding process in the external pad bonding area PA. Similarly, an upper metal pattern 372a may be formed at an upper portion of the first cell area CELL1, and an upper metal pattern 272a may be formed at an upper portion of the peripheral circuit area PERI. The upper metal pattern 372a of the first cell area CELL1 and the upper metal pattern 272a of the peripheral circuit area PERI may be connected to each other by a bonding process.

Common source line contact plugs 380 and 480 may be disposed in the external pad bonding area PA. The common source line contact plugs 380 and 480 may be formed of a conductive material, such as a metal, a metal compound, or polysilicon. The common source line contact plug 380 of the first cell area CELL1 may be electrically connected to the common source line 320, and the common source line contact plug 480 of the second cell area CELL2 may be electrically connected to the common source line 420. A first metal line 350a and a second metal line 360a may be sequentially stacked on the common source line contact plug 380 of the first cell area CELL1, and a first metal line 450a and a second metal line 460a may be sequentially stacked on the common source line contact plug 480 of the second cell area CELL2.

Input/output pads 205, 405, and 406 may be disposed in the external pad bonding area PA. Referring to FIG. 20, a lower insulating layer 201 may be formed on a lower surface of the first substrate 210 to cover the lower surface of the first substrate 210, and a first input/output pad 205 may be formed on the lower insulating layer 201. The first input/output pad 205 may be connected to at least one of the circuit elements 220a disposed in the peripheral circuit area PERI through a first input/output contact plug 203 and may be separated from the first substrate 210 by the lower insulating layer 201. In addition, a side surface insulating layer may be disposed between the first input/output contact plug 203 and the first substrate 210, and thus, the first input/output contact plug 203 and the first substrate 210 may be electrically separated from each other.

An upper insulating layer 401 may be formed on the third substrate 410 to cover the upper surface of the third substrate 410. A second input/output pad 405 and/or a third input/output pad 406 may be disposed on the upper insulating layer 401. The second input/output pad 405 may be connected to at least one of the circuit elements 220a disposed in the peripheral circuit area PERI through second input/output contact plugs 403 and 303, and the third input/output pad 406 may be connected to at least one of the circuit elements 220a disposed in the peripheral circuit area PERI through third input/output contact plugs 404 and 304.

According to some implementations, the third substrate 410 may not be disposed in an area in which the input/output contact plug is disposed. As shown in an area B, the third input/output contact plug 404 may be separated from the third substrate 410 in a direction substantially parallel to the upper surface of the third substrate 410 and may be connected to the third input/output pad 406 after penetrating an interlayer insulating layer 415 of the second cell area CELL2. In some implementations, the third input/output contact plug 404 may be formed through various processes.

According to some implementations, as shown in an area B1, a third input/output contact plug 404 may extend in the third direction (the Z-axis direction) and may have a diameter that increases as a distance from an upper insulating layer 401 decreases. For example, different from a diameter of the channel structure CH of the area Al that decreases as a distance from the upper insulating layer 401 decreases, the diameter of the third input/output contact plug 404 may increase as the distance from the upper insulating layer 401 decreases. As an example, the third input/output contact plug 404 may be formed after a second cell area CELL2 is bonded to a first cell area CELL1 by a bonding process.

According to some implementations, as shown in an area B2, a third input/output contact plug 404 may extend in the third direction (the Z-axis direction) and may have a diameter that decreases as a distance from an upper insulating layer 401 decreases. For example, similar to the channel structure CH, the diameter of the third input/output contact plug 404 may decrease as the distance from the upper insulating layer 401 decreases. As an example, the third input/output contact plug 404 may be formed together with cell contact plugs 440 before a second cell area CELL2 is bonded to a first cell area CELL1.

According to some implementations, an input/output contact plug may be disposed to overlap a third substrate 410. For instance, as shown in an area C, a second input/output contact plug 403 may be formed to penetrate an interlayer insulating layer 415 of a second cell area CELL2 in the third direction (the Z-axis direction) and may be electrically connected to a second input/output pad 405 through the third substrate 410. In some implementations, the second input/output contact plug 403 and the second input/output pad 405 may be connected to each other in various ways.

According to some implementations, as shown in an area C1, an opening 408 may be defined through a third substrate 410, and a second input/output contact plug 403 may be directly connected to a second input/output pad 405 via the opening 408 defined through the third substrate 410. Accordingly, as shown in the area C1, the second input/output contact plug 403 may have a diameter that increases as a distance from the second input/output pad 405 decreases. However, this is merely an example, and the diameter of the second input/output contact plug 403 may decrease as the distance from the second input/output pad 405 decreases.

According to some implementations, as shown in an area C2, an opening 408 may be defined through a third substrate 410, and a contact 407 may be formed in the opening 408. One end of the contact 407 may be connected to a second input/output pad 405, and the other end of the contact 407 may be connected to a second input/output contact plug 403. Accordingly, the second input/output contact plug 403 may be electrically connected to the second input/output pad 405 through the contact 407 in the opening 408. Accordingly, the contact 407 may have a diameter increasing as a distance from the second input/output pad 405 decreases, and the second input/output contact plug 403 may have a diameter decreasing as the distance from the second input/output pad 405 decreases as shown in the area C2. As an example, the second input/output contact plug 403 may be formed together with cell contact plugs 440 before a second cell area CELL2 is bonded to a first cell area CELL1, and the contact 407 may be formed after the second cell area CELL2 is bonded to the first cell area CELL1.

In addition, according to some implementations, as shown in an area C3, a stopper 409 may be further formed at an upper surface of an opening 408 of a third substrate 410 when compared to the area C2. The stopper 409 may be a metal line disposed on the same layer as a common source line CSL, however, this is merely an example. According to some implementations, the stopper 409 may be a metal line disposed on the same layer as at least one of word lines 430. A second input/output contact plug 403 may be electrically connected to a second input/output pad 405 through a contact 407 and the stopper 409.

Similar to the second and third input/output contact plugs 403 and 404 of the second cell area CELL2, the second and third input/output contact plugs 303 and 304 of the first cell area CELL1 may have a diameter decreasing as a distance from the lower metal pattern 371e decreases or may have a diameter increasing as the distance from the lower metal pattern 371e decreases.

Meanwhile, a slit 411 may be formed in the third substrate 410 according to some implementations. As an example, the slit 411 may be formed at an arbitrary position in the external pad bonding area PA. As an example, as shown in an area D, when viewed in a plane, the slit 411 may be disposed between the second input/output pad 405 and the cell contact plugs 440. However, this is merely an example, and when viewed in the plane, the slit 411 may be formed to allow the second input/output pad 405 to be positioned between the slit 411 and the cell contact plugs 440.

According to some implementations, as shown in an area D1, a slit 411 may be formed to penetrate a third substrate 410. The slit 411 may be used to prevent the third substrate 410 from being slightly cracked when an opening 408 is formed. However, this is merely an example, and the slit 411 may be formed at a depth of approximately 60 to 70% of a thickness of the third substrate 410.

According to some implementations, as shown in an area D2, a conductive material 412 may be formed in a slit 411. The conductive material 412 may be used, for example, to discharge a leakage current generated when circuit elements of an external pad bonding area PA are driven to the outside. In this case, the conductive material 412 may be connected to an external ground line.

According to some implementations, as shown in an area D3, an insulating material 413 may be formed in a slit 411. The insulating material 413 may be formed, for example, to electrically separate a second input/output pad 405 and a second input/output contact plug 403 disposed in an external pad bonding area PA from a word line bonding area WLBA. As the insulating material 413 is formed in the slit 411, a voltage provided through the second input/output pad 405 may be prevented from affecting a metal layer disposed on a third substrate 410 in the word line bonding area WLBA.

The first, second, and third input/output pads 205, 405, and 406 may be selectively formed according to some implementations. As an example, the memory device 100H may include only the first input/output pad 205 disposed above the first substrate 210, may include only the second input/output pad 405 disposed above the third substrate 410, or may include only the third input/output pad 406 disposed above the upper insulating layer 401.

According to some implementations, at least one of the second substrate 310 of the first cell area CELL1 and the third substrate 410 of the second cell area CELL2 may be used as a sacrificial substrate and may be completely or partially removed before or after the bonding process. After the substrate is removed, an additional layer may be provided. As an example, the second substrate 310 of the first cell area CELL1 may be removed before or after the peripheral circuit area PERI is bonded to the first cell area CELL1, and an insulating layer covering an upper surface of the common source line 320 or a conductive layer for the connection of the common source line 320 may be formed. Similarly, the third substrate 410 of the second cell area CELL2 may be removed before or after the first cell area CELL1 is bonded to the second cell area CELL2, and the upper insulating layer 401 covering the upper surface of the common source line 420 or a conductive layer for the connection of the common source line 420 may be formed.

According to some implementations, some of the circuit elements constituting the row decoder formed in the peripheral circuit area PERI may overlap the bit lines disposed in the bit line bonding area BLBA. For example, the decoder area in which the row decoder is disposed may be expanded to the bit line bonding area BLBA. Accordingly, the area to place the row decoder 121 may be secured without increasing the chip size, and the overall chip size may be reduced.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A memory device comprising:
a first semiconductor layer comprising a peripheral circuit; and
a second semiconductor layer on the first semiconductor layer in a vertical direction and comprising a memory cell array electrically connected to the peripheral circuit,
wherein the first semiconductor layer comprises a page buffer area in which a page buffer circuit is disposed,
wherein the second semiconductor layer comprises a cell area in which a plurality of bit lines is arranged at intervals along a first direction, and
wherein a length of the page buffer area in the first direction is different from a length of the cell area in the first direction.

2. The memory device of claim 1, wherein the length of the page buffer area in the first direction is shorter than the length of the cell area in the first direction.

3. The memory device of claim 2,
wherein the second semiconductor layer comprises a plurality of word lines extending in the first direction and electrically connected to the memory cell array,
wherein the first semiconductor layer comprises a decoder area in which a row decoder is disposed, the row decoder being electrically connected to the word lines, and
wherein the decoder area overlaps the cell area when viewed in a horizontal direction.

4. The memory device of claim 3,
wherein the bit lines extend in a second direction and are arranged at intervals in the first direction, and
wherein the page buffer circuit comprises a plurality of page buffer units arranged in the second direction.

5. The memory device of claim 4, wherein at least one of the bit lines does not overlap the page buffer area when viewed in the horizontal direction.

6. The memory device of claim 4, wherein a number of the page buffer units arranged in the second direction is different from a number of the bit lines that overlap the page buffer units when viewed in the horizontal direction among the bit lines.

7. The memory device of claim 2,
wherein the second semiconductor layer further comprises a second metal line that extends in the first direction and electrically connects a first bit line among the bit lines and the page buffer circuit, and
wherein the first bit line does not overlap the page buffer circuit.

8. The memory device of claim 7, wherein the first semiconductor layer comprises:
a first bonding metal;
a first metal line disposed under the first bonding metal and electrically connected to the page buffer circuit; and
a first contact electrically connecting the first bonding metal and the first metal line,
wherein the second semiconductor layer comprises:
a second bonding metal corresponding to the first bonding metal; and
a second contact electrically connecting the second metal line and the first bit line.

9. The memory device of claim 8,
wherein the first bonding metal, the second bonding metal, and the first metal line overlap with each other when viewed in a horizontal direction, and
wherein the first bonding metal, the second bonding metal, and the first metal line do not overlap the first bit line when viewed in the horizontal direction.

10. The memory device of claim 2,
wherein the first semiconductor layer further comprises a first metal line that extends in the first direction and electrically connects a first bit line among the bit lines and the page buffer circuit, and
wherein the first bit line does not overlap the page buffer circuit.

11. The memory device of claim 10, wherein the first semiconductor layer comprises:
a first bonding metal; and
a first contact electrically connecting the first bonding metal and the first metal line, the second semiconductor layer comprises:
a second bonding metal corresponding to the first bonding metal;
a second metal line disposed under the second bonding metal;
a second contact electrically connecting the second metal line and the first bit line; and
a third contact electrically connecting the second metal line and the second bonding metal,
wherein the first bonding metal, the second bonding metal, the second metal line, and the first bit line overlap with each other when viewed in the horizontal direction.

12. The memory device of claim 11, wherein the first bonding metal, the second bonding metal, the second metal line, and the first bit line do not overlap the page buffer area when viewed in the horizontal direction.

13. The memory device of claim 10, wherein the second semiconductor layer further comprises a through via that extends in the vertical direction with respect to the first semiconductor layer and electrically connects the first bit line and the first metal line.

14. The memory device of claim 1, wherein the length of the page buffer area in the first direction is greater than the length of the cell area in the first direction.

15. The memory device of claim 14,
wherein the second semiconductor layer further comprises a step area in which ends of a plurality of word lines extending in the first direction are disposed, and
wherein at least a portion of the page buffer area overlaps the step area when viewed in the horizontal direction.

16. The memory device of claim 15, wherein the first semiconductor layer comprises:
a first bonding metal; and
a first metal line disposed under the first bonding metal and electrically connected to the page buffer circuit, the second semiconductor layer comprises:
a second bonding metal corresponding to the first bonding metal; and
a second metal line disposed under the second bonding metal and electrically connected to a corresponding bit line among the bit lines,
wherein the first bonding metal, the second bonding metal, and the first metal line overlap the step area when viewed in the horizontal direction.

17. A memory device comprising:
a first semiconductor layer comprising a peripheral circuit; and
a second semiconductor layer on the first semiconductor layer along a third direction that is a vertical direction, the second semiconductor layer comprising a memory cell array,
wherein the first semiconductor layer comprises a plurality of page buffer units extending in a first direction, the plurality of page buffer units being arranged in a second direction,
wherein the second semiconductor layer comprises a plurality of bit lines electrically connected to the page buffer units and arranged at intervals along the first direction, and
wherein a value obtained by multiplying a pitch of the bit lines in the first direction by a number of the page buffer units is greater than a length of the page buffer units in the first direction.

18. The memory device of claim 17, wherein at least one of the bit lines does not overlap the page buffer units when viewed in a horizontal direction.

19. The memory device of claim 17, wherein the first semiconductor layer is bonded to the second semiconductor layer by a bonding process.

20. A memory device comprising:
a first semiconductor layer comprising a peripheral circuit; and
a second semiconductor layer on the first semiconductor layer along a third direction that is a vertical direction, the second semiconductor layer comprising a memory cell array,
wherein the first semiconductor layer comprises a plurality of page buffer units extending in a first direction, the plurality of page buffer units being arranged in a second direction,
wherein the second semiconductor layer comprising a plurality of bit lines electrically connected to the page buffer units and arranged at intervals along the first direction, and
wherein a value obtained by multiplying a pitch of the bit lines in the first direction by a number of the page buffer units is smaller than a length of the page buffer units in the first direction.
